(19) United States
(12) Patent Application Publication
(10) Pub. No.: US 2024/0301252 A1
(43) Pub. Date: Sep. 12, 2024

(54) HIGH THIXOTROPIC CURABLE SILICONE COMPOSITION AND CURED PRODUCT THEREOF

(71) Applicants: Rohm and Haas Electronic Materials Korea Ltd., Chungcheongnam-do (KR); DuPont Toray Specialty Materials Kabushiki Kaisha, Tokyo (JP)

(72) Inventors: Hyunji Kang, Gyeonggi-Do (KR); Shunya TAKEUCHI, Ichihara-shi (JP); Mayumi MATSUZAKI, Ichihara-shi (JP); Yuri IGUCHI, Utsunomiya-shi (JP)

(21) Appl. No.: 18/593,521

(22) Filed: Mar. 1, 2024

(30) Foreign Application Priority Data
Mar. 8, 2023 (JP) 2023-035753

(51) Int. Cl. C09J 11/04; C08G 77/00; C08G 77/14; C08G 77/20; C08K 3/22; C08K 3/36; C09J 183/04

(52) U.S. Cl. CPC C09J 11/04; C08K 3/22; C08K 3/36; C09J 183/04; C08G 77/14; C08G 77/20; C08G 77/70; C08G 77/80; C08K 2003/2241

(57) ABSTRACT

A curable silicone composition comprising at least one curing reactive organopolysiloxane in an amount of 65% by weight or more relative to the total weight of the composition, at least one inorganic filler selected from silica, silica-titania composite oxide particle, and a combination thereof, in an amount of 1% by weight or more relative to the total weight of the composition, and at least one additive selected from (C1) organopolysiloxane having at least one organic functional group including at least one polyether structure at molecular side chain and/or molecular terminal; (C2) organosilane compound comprising at least one organic functional group selected from a C₁-C₆alkyl group, aryl group, and epoxy group, (C3) organopolysiloxane having at least one hydroxy group and at least one aryl group; (C4) organosiloxane oligomer having at least one epoxy group; (C5) unsaturated carboxylic acid or an ester thereof, and combinations thereof.

### CROSS-REFERENCE TO RELATED APPLICATIONS

This application claims priority pursuant to 35 U.S.C. 119(a) to Japanese Application No. 2023-035753, filed Mar. 8, 2023, which application is incorporated herein by reference in its entirety.

### TECHNICAL FIELD

The present invention relates to a curable silicone composition having a high thixotropic property and a cured product thereof.

### BACKGROUND ART

Curable silicone compositions are utilized in a wide range of industrial fields because they form cured products having excellent heat resistance, cold resistance, electrical insulation, weather resistance, water repellency, and transparency. The cured product of such a curable silicone composition is also suitable as a sealant for optical materials, such as light emitting diodes (LEDs), because it hardly becomes discolored as compared with other organic materials, and there is less deterioration of physical properties, such as durability.

In recent years, various curable silicone compositions have been reported as silicone encapsulants used in optical semiconductor devices such as light emitting diodes (LEDs).

For example, JP-T-2012-507582 discloses a hydrosilylation reaction-curable organopolysiloxane composition comprising:
(A) a methylphenylalkenylpolysiloxane that has at least two silicon-bonded alkenyl groups per molecule, wherein diphenylsiloxane units are no more than 5 mole % of the total siloxane units and phenyl groups are at least 20 mole % of the total silicon-bonded organic groups in the molecule,
(B) a methylphenylhydrogenpolysiloxane that has at least two silicon-bonded hydrogen atoms per molecule, wherein diphenylsiloxane units are no more than 5 mole % of the total siloxane units and phenyl groups are at least 20 mole % of the total silicon-bonded organic groups in the molecule, and
(C) a hydrosilylation reaction catalyst, wherein the diphenylsiloxane units are no more than 5 mole % of the total siloxane units in this composition.

Also, JP-A-2014-159586 discloses a silicone resin composition for coating a light transmitting surface of an optoelectronic device, the composition comprising:
a plurality of liquid components including:
a linear organopolysiloxane component comprising at least one unsaturated aliphatic group participating in hydrosilylation reaction in a molecule;
an organohydrogenpolysiloxane component; and
a platinum metal catalyst;
said linear organopolysiloxane component having a sufficiently low proportion of organosiloxanes having molecular weights of up to about 1000, such that when said silicone resin product is cured said cured product comprises less than about 10% of said organosiloxanes having molecular weights of up to about 1000.

In addition, JP-A-2017-036416 discloses a curable silicone resin composition comprising a component (A), a component (B), a component (C), a component (D), and a component (E):
(A) a polyorganosiloxane having one or more hydrosilyl groups in a molecule and having no aliphatic unsaturated group;
(B) a hydrosilylation catalyst comprising a platinum group metal;
(C) branched polyorganosiloxane having one or more alkenyl groups in a molecule;
(D) silica filler having a mean particle diameter of primary particles of 5-5000 nm; and
(E) polyether-modified leveling agent.

In addition, JP-A-2020-100683 discloses a curable silicone resin composition comprising a component (A), a component (B), a component (C), and a component (D):
(A) a polyorganosiloxane having one or more hydrosilyl groups in a molecule and having no aliphatic unsaturated group;
(B) a branched polyorganosiloxane having one or more alkenyl groups in a molecule (except for the component (C);
(C) branched polyorganosiloxane having three or more alkenyl groups in a molecule and having a molecular weight of 1000 or less; and
(D) a hydrosilylation catalyst comprising a platinum group metal.

However, since conventional curable silicone compositions may have an insufficient thixotropic property, there may be a problem where an applied curable silicone composition may flow and a cured product having a desired shape may not be obtained even though an appropriate amount of the silicone composition is applied to an optical semiconductor on a support substrate using a dispenser. Also, it can be a problem if the conventional curable silicone composition do not possess a long shelf life for storage.

### SUMMARY OF THE INVENTION

An objective of the present invention is to provide a curable silicone composition which possesses a high thixotropic property such that a dispensed composition maintains its shape on a substrate effectively before and/or after curing at a high temperature

Another objective of the present invention is to provide a curable silicone composition having sufficient storage stability.

Another objective of the present invention is to provide a curable silicone composition having a high transparency.

The above objective of the present invention can be achieved by a curable silicone composition comprising:
(A) at least one curing reactive organopolysiloxane in an amount of 65% by weight or more relative to the total weight of the composition;
(B) at least one inorganic filler selected from silica, silica-titania composite oxide particle, alumina, clay, talc, and combinations thereof, in an amount of 1% by weight or more relative to the total weight of the composition; and
(C) at least one additive selected from (C1) organopolysiloxane having at least one organic functional group including at least one polyether structure at molecular side chain and/or molecular terminal; (C2) organosilane compound comprising at least one C₁-C₆ alkyl group, aryl group, and/or epoxy group, (C3) organopolysiloxane having at least one hydroxy group and at least one aryl group; (C4) organosiloxane oligomer having at least one epoxy group; (C5) unsaturated carboxylic acid or an ester thereof, and combinations thereof.

The (A) curing reactive organopolysiloxane may be hydrosilylation reaction-reactive organopolysiloxane.

The (B) inorganic filler may be present in an amount of more than 1.5% by weight and 30% by weight or less relative to the total weight of the composition.

The (C3) organopolysiloxane having at least one hydroxy group may comprise the hydroxy group(s) in an amount of 0.1 mol % or more relative to the total amount of the silicon atom-bonded functional groups.

The curable silicone composition may comprise (C1) organopolysiloxane having at least one organic functional group including at least one polyether structure at a molecular side chain and/or molecular terminal.

The (C1) organopolysiloxane may be present in an amount of 0.01% by weight or more and 10% by weight or less relative to the total weight of the composition.

The curable silicone composition may comprise a (C2) organosilane compound comprising at least one organic functional group comprising at least one C₁-C₆ alkyl group, aryl group, and/or epoxy group

The (C2) organosilane compound may be present in an amount of 0.01% by weight or more and 5% by weight or less relative to the total weight of the composition.

The curable silicone composition may comprise both of the (C1) organopolysiloxane having at least one organic functional group including at least one polyether structure at a molecular side chain and/or molecular terminal and the (C2) organosilane compound comprising at least one organic functional group selected from a C₁-C₆ alkyl group, aryl group, and epoxy group.

The present invention also relates to a sealing material formed with the curable silicone composition according to the present invention.

The present invention also relates to an optical semiconductor device provided with the sealing material according to the present invention.

### Effects of the Invention

The present invention can provide a curable silicone composition which can form a cured product with an improved morphological stability.

Also, the present invention can provide a curable silicone composition with improved storage stability.

### MODE FOR CARRYING OUT THE INVENTION

After diligent research, the inventors have surprisingly discovered that a combination of components (A) to (C) of the present invention can provide a curable silicone composition with a good morphological stability and/or long shelf-life, and thus completed the present invention.

Thus, the composition according to the present invention is a curable silicone composition comprising:
(A) at least one curing reactive organopolysiloxane in an amount of 65% by weight or more relative to the total weight of the composition;
(B) at least one inorganic filler selected from silica, a silica-titania composite oxide particle, alumina, clay, talc, and a combination thereof, in an amount of 1% by weight or more relative to the total weight of the composition; and
(C) at least one additive selected from (C1) organopolysiloxane having at least one organic functional group including at least one polyether structure at molecular side chain and/or molecular terminal; (C2) organosilane compound comprising at least one organic functional group selected from a C₁-C₆ alkyl group, aryl group, and epoxy group; (C3) organopolysiloxane having at least one hydroxy group and at least one aryl group; (C4) organosiloxane oligomer having at least one epoxy group; (C5) unsaturated carboxylic acid or an ester thereof, and combinations thereof.

Hereinafter, the composition, process, and use according to the present invention will be explained in a more detailed manner.

### [Curable Silicone Composition]

The curable silicone composition according to the present invention comprises (A) at least one reactive organopolysiloxane, (B) at least on inorganic filler selected from silica, silica-titania composite oxide particle, alumina, clay, talc, and a combination thereof, and (C) at least one additive selected from (C1) organopolysiloxane having at least one organic functional group including at least one polyether structure at molecular side chain and/or molecular terminal; (C2) organosilane compound comprising at least one organic functional group selected from a C₁-C₆ alkyl group, aryl group, and/or epoxy group; (C3) organopolysiloxane having at least one hydroxy group and at least one aryl group; (C4) organosiloxane oligomer having at least one epoxy group; (C5) unsaturated carboxylic acid or an ester thereof; and combinations thereof.

Each of the components of the curable silicone composition will be explained below.

### (A) Curing Reactive Organopolysiloxane

The curable silicone composition according to the present invention comprises at least one curing reactive organopolysiloxane. The term “curing reactive organopolysiloxane” here means an organopolysiloxane compound having at least one functional group capable of a curing reaction.

The (A) organopolysiloxane is different from any of the (C) additives explained below.

The curing reaction mechanism of the curing reactive organopolysiloxane is not particularly limited. Examples of the curing reaction mechanism include: a hydrosilylation reaction curing type using an alkenyl group and a silicon atom-bonded hydrogen atom; a dehydration condensation reaction curing type or a dealcoholization condensation reaction curing type using a silanol group and/or a silicon atom-bonded alkoxy group; a peroxide curing reaction type using an organic peroxide; and a radical reaction curing type using high energy ray irradiation on a mercapto group; and the like. Among these curing reaction mechanisms, hydrosilylation reaction curing is preferable because the entire composition is cured relatively quickly and the reaction can be easily controlled. These curing reactions proceed with heating, irradiating with high energy radiation, or a combination thereof.

Preferably the curing reaction proceeds with heating. In one preferred embodiment of the present invention, the curable silicone composition of the present invention is a heat-curable silicone composition. The composition according to the present invention can show a good morphological stability even at a high temperature, such as from 150° C. to 190° C.

When the curing reactive organopolysiloxane is cured by the hydrosilylation curing mechanism, i.e., the curable organopolysiloxane of the present invention is cured via hydrosilylation reaction, the (A) curing reactive organopolysiloxane can contain (A1) alkenyl group-containing organopolysiloxane having at least two silicon-bonded alkenyl groups per molecule, (A2) organohydrogen polysiloxane having at least two silicon-bonded hydrogen atoms per molecule, and (A3) hydrosilylation catalyst. The case where the curing of the curable silicone composition of the present is a hydrosilylation reaction is described in more detail below.

### (A1) Alkenyl Group-Containing Organopolysiloxane

Component (A1) is an alkenyl group-containing organopolysiloxane having at least two silicon atom-bonded alkenyl groups per molecule. The composition according to the present invention may comprise one type of the (A1) alkenyl group-containing organopolysiloxane or may comprise two or more types of the (A1) alkenyl group-containing organopolysiloxane in combination.

The (A1) alkenyl group-containing organopolysiloxane may be linear, branched, partially-branched, cyclic, or resinous. The term “linear” here means that the organopolysiloxane has a straight chain structure in the molecule and does not have a branched chain nor a branched structure. The term “resinous” here means that the organopolysiloxane has a branched or three-dimensional network structure in the molecule.

The alkenyl group included in component (A1) may include C₂₋₁₂ alkenyl groups, such as a vinyl, allyl, butenyl, pentenyl, hexenyl, heptenyl, octenyl, nonenyl, decenyl, undecenyl, and dodecenyl groups; and preferably a vinyl group.

Other silicon atom-bonded functional groups other than alkenyl groups included in component (A1) may include C₁₋₁₂ alkyl groups such as methyl, ethyl, propyl, isopropyl, butyl, isobutyl, cert-butyl, pentyl, neopentyl, hexyl, cyclohexyl, heptyl, octyl, nonyl, decyl, undecyl and dodecyl groups; C₆₋₁₂ aryl groups such as phenyl, tolyl, xylyl and naphthyl groups; C₇₋₁₂ aralkyl groups such as benzyl, phenethyl, and phenylpropyl groups; and groups obtained by substituting some or all of the hydrogen atoms in these groups with halogen atoms such as fluorine, chlorine or bromine atoms. It should be noted that a small amount of an alkoxy group such as a methoxy or ethoxy group may be bonded to the silicon atom in the component (A1), provided that this does not adversely affect the aim of the present invention. Preferably, the silicon atom-bonded functional groups other than alkenyl groups comprise a C₁₋₁₂ alkyl group, in particular a methyl group. Component (A1) may include no thiol groups or no hydroxy groups.

In one embodiment of the present invention, the (A1) alkenyl group-containing organopolysiloxane comprises at least one resinous organopolysiloxane which can be represented by the following formula (I-a):

(R¹₃SiO_{1/2})ₐ(R¹₂SiO_{2/2})_{b}(R¹SiO_{3/2})_{c}(SiO_{4/2})_{d}(XO_{1/2})ₑ average unit formula (I-a):

in which, R¹ indicates the same or different monovalent hydrocarbon, which can be optionally substituted with at least one halogen, wherein at least two of R¹ per molecule represent alkenyl groups; X represents an alkyl group; and 0≤a<1, 0≤b<1, 0≤c<0.95, 0≤d<0.9, 0≤e<0.4, a+b+c+d=1.0, and c+d>0 are satisfied. One type of resinous organopolysiloxane or two or more types of resinous organopolysiloxane can be used as the (A1) alkenyl group-containing organopolysiloxane.

The monovalent hydrocarbon for R¹ in formula (I-a), which can be optionally substituted with at least one halogen, may include, C₁₋₁₂ alkyl groups such as methyl, ethyl, propyl, isopropyl, butyl, isobutyl, cert-butyl, pentyl, neopentyl, hexyl, cyclohexyl, heptyl, octyl, nonyl, decyl, undecyl and dodecyl groups; C₂₋₁₂ alkenyl groups, such as a vinyl, allyl, butenyl, pentenyl, hexenyl, heptenyl, octenyl, nonenyl, decenyl, undecenyl, and dodecenyl groups; C₆₋₁₂ aryl groups such as phenyl, tolyl, xylyl and naphthyl groups; C₇₋₁₂ aralkyl groups such as benzyl, phenethyl, and phenylpropyl groups; and groups obtained by substituting some or all of the hydrogen atoms in these groups with halogen atoms such as fluorine, chlorine or bromine atoms. The monovalent hydrocarbon in R¹ may include a small amount of alkoxy group such as a methoxy or ethoxy group, provided that this does not adversely affect the aim of the present invention. Preferably, the monovalent hydrocarbon in R¹ represents a C₁₋₁₂ alkyl group, in particular a methyl group, C₂₋₁₂ alkenyl groups, in particular a vinyl group, or a C₆₋₁₂ aryl group, in particular a phenyl group.

In formula (I-a), X represents an alkyl group. The alkyl group in X preferably represents a C₁₋₃ alkyl group such as a methyl, ethyl, or propyl group.

In one embodiment of the present invention, in formula (I-a), a ranges preferably from 0.05≤a≤0.6, more preferably in the range of 0.1≤a≤0.45, and even more preferably in the range of 0.15≤a≤0.35. In formula (I-a), b ranges preferably from 0≤b≤0.5, more preferably from 0≤b≤0.3, and even more preferably from 0≤b≤0.1. In formula (I-a), c ranges preferably from 0.3≤c≤0.9, more preferably from 0.5≤c≤0.85, and even more preferably from 0.6≤c≤0.8. In formula (I-a), d ranges preferably from 0≤d≤0.5, more preferably from 0≤d≤0.3, and even more preferably from 0≤d≤0.1. In formula (I-a), e ranges preferably from 0≤e≤0.2, more preferably from 0≤e≤0.1, and even more preferably from 0≤e≤0.05. In the present specification, any combination of an upper numerical limit and a lower numerical limit is available to represent a certain numerical range.

In another embodiment of the present invention, in formula (I-a), a ranges preferably from 0.3≤a≤0.9, more preferably in the range of 0.45≤a≤0.85, and even more preferably in the range of 0.6≤a≤0.8. In formula (I-a), b ranges preferably from 0≤b≤0.5, more preferably from 0≤b≤0.3, and even more preferably from 0≤b≤0.1. In formula (I-a), c ranges preferably from 0.05≤c≤0.5, more preferably from 0.1≤c≤0.4, and even more preferably from 0.15≤c≤0.3. In formula (I-a), d ranges preferably from 0≤d≤0.5, more preferably from 0≤d≤0.3, and even more preferably from 0≤d≤0.1. In formula (I-a), e ranges preferably from 0≤e≤0.2, more preferably from 0≤e≤0.1, and even more preferably from 0≤e≤0.05. In the present specification, any combination of an upper numerical limit and a lower numerical limit is available to represent a certain numerical range.

In one embodiment of the present invention, in formula (I-a), c is more than 0, i.e., the (A1) resinous organopolysiloxane comprises at least one T siloxane unit represented by (SiO_{3/2}). In this embodiment, the (A1) resinous organopolysiloxane may or may not comprise a Q siloxane unit represented by (SiO_{4/2}), however, it preferably does not comprise any Q units.

In one embodiment of the present invention, the resinous organopolysiloxane as the component (A1), such as those represented by formula (I-a), may be present in an amount of 40% by weight or more, preferably 50% by weight or more, more preferably 55% by weight or more, and in particular 60% by weight or more, and may be present in an amount of 95% by weight or less, preferably 90% by weight or less, and more preferably 85% by weight or less, and even more preferably 80% by weight or less, relative to the total weight of the composition. In the present specification, any combination of an upper numerical limit and a lower numerical limit is available to represent a certain numerical range.

In another embodiment of the present invention, the (A1) alkenyl group-containing organopolysiloxane comprises at least one MQ resin composed of only M unit and Q unit, which can be represented by the following formula (I-b):

(R¹₃SiO_{1/2})ₛ(SiO_{4/2})ₜ average unit formula (I-b):

in which, R¹ indicates the same or different monovalent hydrocarbon, which can be optionally substituted with at least one halogen, wherein at least two of R¹ per molecule represent alkenyl groups; and 0<s<1, 0<t<1, and s+t=1.0 are satisfied. One type of MQ resin or two or more types of MQ resin can be used as the (A1) alkenyl group-containing organopolysiloxane.

The same definition for R¹ in formula (I-a) can be applied to R¹ in formula (I-b).

In one embodiment of the present invention, in formula (I-b), s preferably ranges from 0.25≤s≤0.8, more preferably in the range of 0.3≤s≤0.7, and even more preferably in the range of 0.35≤s≤0.65. In formula (I-b), t preferably ranges from 0.2≤t≤0.8, more preferably from 0.3≤t≤0.7, and even more preferably from 0.35≤t≤0.6.

In one embodiment of the present invention, the MQ resin as the component (A1) may be present in an amount of 1% by weight or more, preferably 2% by weight or more, more preferably 3% by weight or more, and in particular 4% by weight or more, and may be present in an amount of 70% by weight or less, preferably 60% by weight or less, more preferably 55% by weight or less, and even more preferably 50% by weight or less, relative to the total weight of the composition.

Any combination of the upper limit and the lower limit is available.

In another embodiment of the present invention, the (A1) alkenyl group-containing organopolysiloxane comprises at least one linear organopolysiloxane which can be represented by the following formula (I-c):

R¹₃SiO(R¹₂SiO)ₘSiR¹₃ average structural formula (I-c):

in which, R¹ indicates the same or different monovalent hydrocarbon, which can be optionally substituted with at least one halogen, wherein at least two of R¹ per molecule represent alkenyl groups; and m ranges from 1 to 1,000. One type of linear organopolysiloxane or two or more types of linear organopolysiloxane can be used as the (A1) alkenyl group-containing organopolysiloxane.

The same definition for R¹ in formula (I-a) can be applied to R¹ in formula (I-c).

In formula (I-c), m preferably ranges from 5 to 800, and more preferably from 10 to 700, and even more preferably ranges from 15 to 600.

In one preferred embodiment of the present invention, the linear organopolysiloxane of component (A1) can be linear dimethylpolysiloxane comprising dimethylvinylsiloxy groups at both ends of the molecular chain.

In one embodiment of the present invention, the linear organopolysiloxane as component (A1) may be present in an amount of 5% by weight or more, preferably 10% by weight or more, and more preferably 15% by weight or more, and may be present in an amount of 70% by weight or less, preferably 60% by weight or less, and more preferably 50% by weight or less, relative to the total weight of the composition. Any combination of the upper limit and the lower limit is available.

In another embodiment of the present invention, the (A1) alkenyl group-containing organopolysiloxane comprises at least one cyclic organopolysiloxane which can be represented by the following formula (I-d):

(R¹SiO)ₙ average structural formula (I-d):

in which, R¹ indicates the same or different monovalent hydrocarbon, which can be optionally substituted with at least one halogen, wherein at least two of R¹ per molecule represent alkenyl groups; and n is an integer from 4 to 50. One type of cyclic organopolysiloxane or two or more types of cyclic organopolysiloxane can be used as the (A1) alkenyl group-containing organopolysiloxane.

The same definition for R¹ in formula (I-a) can be applied to R¹ in formula (I-d).

In formula (I-d), n may be an integer from 4 to 30, preferably from 4 to 20, more preferably from 4 to 10, and in particular 4 to 8.

The weight-average molecular weight of the cyclic organopolysiloxane as component (A1) is preferably 3,000 or less, more preferably 2,000 or less, even more preferably 1,000 or less, and in particular 500 or less. The lower limit of the weight-average molecular weight of the cyclic organopolysiloxane as component (A1) is not particularly limited, but for example 100 or more. The weight-average molecular weight can be measured (in terms of polystyrene) using gel permeation chromatography (GPC).

In one embodiment of the present invention, the cyclic organopolysiloxane as the component (A1) may be present in an amount of 0.05% by weight or more, preferably 0.1% by weight or more, and more preferably 0.15% by weight or more, and may be present in an amount of 3% by weight or less, preferably 1% by weight or less, and more preferably 0.5% by weight or less, relative to the total weight of the composition. Any combination of the upper limit and the lower limit is available.

In another embodiment of the present invention, the (A1) alkenyl group-containing organopolysiloxane comprises at least one epoxy group-containing resinous organopolysiloxane which can be represented by the following formula (I-e):

(R²₃SiO_{1/2})ₐ(R²₂SiO_{2/2})_{b}(R²SiO_{3/2})_{c}(SiO_{4/2})_{d}(XO_{1/2})ₑ average structural formula (I-e):

in which, R² indicates the same or different monovalent hydrocarbon, which can be optionally substituted with at least one halogen, wherein at least two of R² per molecule represent alkenyl groups and at least one of R² per molecule represents an epoxy group-containing organic group; X represents an alkyl group; and 0≤a<1, 0≤b<1, 0≤c<0.95, 0≤d<0.9, 0≤e<0.4, a+b+c+d=1.0, and c+d>0 are satisfied. One type of epoxy group-containing resinous organopolysiloxane or two or more types of epoxy group-containing resinous organopolysiloxane can be used as the (A1) alkenyl group-containing organopolysiloxane.

The monovalent hydrocarbon for R², which can be optionally substituted with at least one halogen, may include, C₁₋₁₂ alkyl groups such as methyl, ethyl, propyl, isopropyl, butyl, isobutyl, cert-butyl, pentyl, neopentyl, hexyl, cyclohexyl, heptyl, octyl, nonyl, decyl, undecyl and dodecyl groups; C₂₋₁₂ alkenyl groups, such as a vinyl, allyl, butenyl, pentenyl, hexenyl, heptenyl, octenyl, nonenyl, decenyl, undecenyl, and dodecenyl groups; C₆₋₁₂ aryl groups such as phenyl, tolyl, xylyl and naphthyl groups; C₇₋₁₂ aralkyl groups such as benzyl, phenethyl, and phenylpropyl groups; epoxy group-containing organic group including glycidoxyalkyl groups, such as 2-glycidoxyethyl group, 3-glycidoxypropyl group, and 4-glycidoxybutyl group; epoxycycloalkyl groups, such as 2-(3,4-epoxycyclohexyl) ethyl group, 3-(3,4-epoxycyclohexyl)-propyl group; epoxyalkyl groups, such as 3,4-epoxybutyl group and 7,8-epoxyoctyl group; and groups obtained by substituting some or all of the hydrogen atoms in these groups with halogen atoms such as fluorine, chlorine or bromine atoms. The monovalent hydrocarbon in R² may include a small amount of alkoxy group such as a methoxy or ethoxy group, provided that this does not adversely affect the aim of the present invention. Preferably, the monovalent hydrocarbon in R² represents a C₁₋₁₂ alkyl group, in particular a methyl group, C₂₋₁₂ alkenyl groups, in particular a vinyl group, a C₆₋₁₂ aryl group, in particular a phenyl group, and glycidoxyalkyl groups, in particular 3-glycidoxypropyl group.

In formula (I-e), X represents an alkyl group. The alkyl group in X preferably represents a C₁₋₃ alkyl group such as a methyl, ethyl, or propyl group.

In one embodiment of the present invention, in formula (I-e), a ranges preferably from 0.≤a≤0.5, more preferably in the range of 0≤a≤0.35, and even more preferably in the range of 0≤a≤0.25. In formula (I-e), b ranges preferably from 0.1≤b≤0.8, more preferably from 0.15≤b≤0.75, and even more preferably from 0.2≤b≤0.7. In formula (I-e), c ranges preferably from 0.15≤c≤0.7, more preferably from 0.2≤c≤0.6, and even more preferably from 0.25≤c≤0.5. In formula (I-e), d ranges preferably from 0≤d≤0.5, more preferably from 0≤d≤0.3, and even more preferably from 0≤d≤0.1. In formula (I-e), e ranges preferably from 0≤e≤0.4, more preferably from 0≤e≤0.3, and even more preferably from 0≤e≤0.2.

In one embodiment of the present invention, the epoxy group-containing resinous organopolysiloxane as the component (A1) may be present in an amount of 0.5% by weight or more, preferably 1% by weight or more, and more preferably 1.5% by weight or more, and may be present in an amount of 10% by weight or less, preferably 7% by weight or less, and more preferably 5% by weight or less, relative to the total weight of the composition. Any combination of the upper limit and the lower limit is available.

In one embodiment of the present invention, the (A1) organopolysiloxane comprises alkenyl groups at the end of the molecule. This means that the (A1) organopolysiloxane comprises alkenyl groups at M siloxane units represented by (SiO_{1/2}). The (A1) organopolysiloxane may or may not comprise alkenyl groups at D siloxane units represented by (SiO_{2/2}) and/or T units, however, it preferably does not comprise alkenyl groups at D nor T units.

The epoxy group-containing resinous organopolysiloxane as the component (A1) can be distinguished from (C4) organosiloxane oligomer having at least one epoxy group descried below, in that epoxy group-containing resinous organopolysiloxane as the component (A1) comprises greater number of siloxane units than (C4) organosiloxane oligomer having at least one epoxy group. For example, the epoxy group-containing resinous organopolysiloxane as the component (A1) comprises more than 20 siloxane units, and more preferably more than 25 siloxane units.

The amount of the alkenyl groups relative to the total amount of the silicon atom-bonded functional groups in the (A1) organopolysiloxane is not particularly limited, but for example 0.01 mol % or more, preferably 0.1 mol % or more, more preferably 0.2 mol % or more, and in particular 0.3 mol % or more, and in general 55 mol % or less, preferably 45 mol % or less, more preferably 35 mol % or less, and in particular 30 mol % or less, relative to the total amount of the silicon atom-bonded functional groups. Any combination of the upper limit and the lower limit is available. The amount of the alkenyl groups can be measured, for example, with analytical methods such as Fourier transform infrared spectroscopy (FT-IR) or nuclear magnetic resonance (NMR), or the following titration method.

The method for quantifying the amount of alkenyl groups in organopolysiloxane by the titration method will be described below. The content of alkenyl groups in organopolysiloxane can be accurately quantified by the titration method known as the Wijs method. The principle is described below. First, alkenyl groups present in organopolysiloxane raw materials and iodine monochlorides are subjected to an addition reaction as shown in Equation (1). Next, by the reaction represented by Equation (2), iodine monochlorides in an excess quantity are reacted with potassium iodides so as to be released as iodines. The free iodines are then titrated with a sodium thiosulfate solution.

CH₂═CH—+2ICl→CH₂I—CHCl—+ICl (excess quantity) Equation (1)

ICl+KI→I₂+KCl Equation (2)

The amount of the alkenyl groups present in the organopolysiloxane can be quantified from the difference between the amounts of sodium thiosulfate required for the titration above and for a blank solution prepared separately.

In one preferred embodiment of the present invention, the (A1) organopolysiloxane comprises at least one aryl group in the silicon atom-bonded functional groups. This means that at least one of R¹ in formula (I-a), (I-b), and/or (I-c) may represent an aryl group. In one preferred embodiment of the present invention, the (A1) organopolysiloxane comprises at least one aryl group at a D unit or T unit. The (A1) organopolysiloxane may or may not comprise aryl groups at an M unit, but preferably does not comprise any aryl groups at an M unit. The aryl group can be selected from C₆₋₁₂ aryl groups such as a phenyl, tolyl, xylyl and naphthyl group.

When the (A1) organopolysiloxane comprises aryl groups per molecule, the content of the aryl groups in the (A1) organopolysiloxane is not particularly limited, but in general 1 mol % or more, preferably 3 mol % or more, more preferably 5 mol % or more, even more preferably 10 mol % or more, and in particular 15 mol % or more, and in general 60 mol % or less, preferably 55 mol % or less, more preferably 50 mol % or less, even more preferably 45 mol % or less, relative to the total amount of the silicon atom-bonded functional groups. Any combination of the upper limit and the lower limit is available. The amount of the aryl groups can be measured, for example, with analytical methods such as Fourier transform infrared spectroscopy (FT-IR) or nuclear magnetic resonance (NMR), or the following titration method.

In one another embodiment of the present invention, the (A1) organopolysiloxane does not comprise any aryl groups in the silicon atom-bonded functional groups. In this embodiment, the (A1) organopolysiloxane may be MQ resin, such as those represented by formula (I-b) above, linear organopolysiloxane, such as those represented by formula (I-c) above, vinylmethylsiloxane resin, and the like.

As specific examples of the vinylmethylsiloxane resin which can be used in the present invention, mention can be made of those represented by the following formula (V):

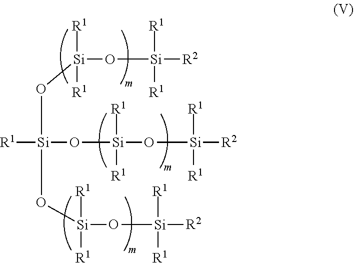

wherein, R¹ and R² each independently represent a hydrocarbon including an alkenyl group, wherein at least two of R² are alkenyl groups, m represents an integer of 1 or more and n represents 0 or an integer of 1 to 5. The hydrocarbon and an alkenyl group in formula (V) are the same as those explained for the component (A1) above.

In formula (V), m is preferably 1 to 20, more preferably 1 to 10, and still more preferably 1 to 5.

The weight-average molecular weight of the vinylmethylsiloxane resin is not particularly limited, but is preferably 300 to 5,000, more preferably 300 to 2,500, and still more preferably 500 to 1,500. The weight-average molecular weight can be measured (in terms of polystyrene) using gel permeation chromatography (GPC).

As a commercial product of the vinylmethylsiloxane resin represented by formula (V) above, mention can be made of MTV-112 (trade name) manufactured by GELEST, INC.

The viscosity of the (A1) organopolysiloxane is not particularly limited, but may be for example 5 mPa to 5,000 mPa at 25° C. The viscosity of organopolysiloxane components herein can be measured with a rotational viscometer compliant with JIS K7117-1.

The (A1) alkenyl group-containing organopolysiloxane may be present in an amount of 50% by weight or more, preferably 60% by weight or more, more preferably 65% by weight or more, and in particular 70% by weight or more, and may be present in an amount of 95% by weight or less, preferably 90% by weight or less, and more preferably 85% by weight or less, relative to the total weight of the composition. Any combination of the upper limit and the lower limit is available.

### (A2) Organohydrogen Polysiloxane

Component (A2) is organohydrogen polysiloxane having at least two silicon atom-bonded hydrogen atoms per molecule. The composition according to the present invention may comprise one type of the (A2) organohydrogen polysiloxane or may comprise two or more types of the (A2) organohydrogen polysiloxane in combination.

The (A2) organohydrogen polysiloxane may be linear, branched, partially-branched, cyclic, or resinous. Preferably, the (A2) organohydrogen polysiloxane is selected from resinous organohydrogen polysiloxane, linear organohydrogen polysiloxane, and a combination thereof.

Other silicon atom-bonded organic functional groups other than a hydrogen atom included in component (A2) may include a monovalent hydrocarbon other than an alkenyl group, for example, C₁₋₁₂ alkyl groups such as methyl, ethyl, propyl, isopropyl, butyl, isobutyl, cert-butyl, pentyl, neopentyl, hexyl, cyclohexyl, heptyl, octyl, nonyl, decyl, undecyl and dodecyl groups; C₆₋₁₂ aryl groups such as phenyl, tolyl, xylyl and naphthyl groups; C₇₋₁₂ aralkyl groups such as benzyl, phenethyl, and phenylpropyl groups; and groups obtained by substituting some or all of the hydrogen atoms in these groups with halogen atoms such as fluorine, chlorine or bromine atoms. It should be noted that a small amount of alkoxy group such as methoxy or ethoxy group may be bonded to the silicon atom in the component (A2), provided that this does not adversely affect the aim of the present invention. Preferably, the silicon atom-bonded organic functional groups other than alkenyl groups comprise a C₁₋₁₂ alkyl group, in particular a methyl group and a C₆₋₁₂ aryl group, in particular a phenyl group. The (A2) organohydrogen polysiloxane may not include any hydroxy groups.

In one embodiment of the present invention, the (A2) organohydrogen polysiloxane comprises resinous organohydrogen polysiloxane which can be represented by the following formula (II-a):

(R³₃SiO_{1/2})ₐ(R³₂SiO_{2/2})_{b}(R³SiO_{3/2})_{c}(SiO_{4/2})_{d}(XO_{1/2})ₑ average unit formula (II-a):

in which, R³ indicates a hydrogen atom or the same or different monovalent hydrocarbon other than an alkenyl group, which can be optionally substituted with at least one halogen, wherein at least two of R³ per molecule represent hydrogen atoms; X represents an alkyl group; and 0≤a<1, 0≤b<1, 0≤c<0.95, 0≤d<0.9, 0≤e<0.4, a+b+c+d=1.0, and c+d>0 are satisfied. One type of resinous organohydrogen polysiloxane or two or more types of resinous organohydrogen polysiloxane can be used as the (A2) organohydrogen polysiloxane.

The monovalent hydrocarbon other than an alkenyl group for R³ in formula (II-a), which can be optionally substituted with at least one halogen, may include, C₁₋₁₂ alkyl groups such as methyl, ethyl, propyl, isopropyl, butyl, isobutyl, cert-butyl, pentyl, neopentyl, hexyl, cyclohexyl, heptyl, octyl, nonyl, decyl, undecyl and dodecyl groups; C₆₋₁₂ aryl groups such as phenyl, tolyl, xylyl and naphthyl groups; C₇₋₁₂ aralkyl groups such as benzyl, phenethyl, and phenylpropyl groups; and groups obtained by substituting some or all of the hydrogen atoms in these groups with halogen atoms such as fluorine, chlorine or bromine atoms. The monovalent hydrocarbon in R³ may include a small amount of alkoxy group such as a methoxy or ethoxy group, provided that this does not adversely affect the aim of the present invention. Preferably, the monovalent hydrocarbon in R³ represents a C₁₋₁₂ alkyl group, in particular a methyl group or a C₆₋₁₂ aryl group, in particular a phenyl group.

In formula (II-a), X represents an alkyl group. The alkyl group in X preferably represents a C1-3 alkyl group such as a methyl, ethyl, or propyl group.

In one embodiment of the present invention, in formula (II-a), a ranges preferably from 0.1≤a≤0.9, more preferably in the range of 0.3≤a≤0.8, and even more preferably in the range of 0.5≤a≤0.7. In formula (II-a), b ranges preferably from 0≤b≤0.5, more preferably from 0≤b≤0.3, and even more preferably from 0≤b≤0.1. In formula (II-a), c ranges preferably from 0.1≤c≤0.7, more preferably from 0.2≤c≤0.6, and even more preferably from 0.3≤c≤0.5. In formula (II-a), d ranges preferably from 0≤d≤0.4, more preferably from 0≤d≤0.25, and even more preferably from 0≤d≤0.1. In formula (II-a), e ranges preferably from 0≤e≤0.15, more preferably from 0≤e≤0.1, and even more preferably from 0≤e≤0.05.

In this embodiment of the present invention, in formula (II-a), c is more than 0, i.e., the (A2) resinous organohydrogen polysiloxane comprises at least one T siloxane unit represented by (SiO_{3/2}). In this embodiment, the (A2) resinous organohydrogen polysiloxane may or may not comprise a Q siloxane unit represented by (SiO_{4/2}), however, it preferably does not comprise any Q units.

In one embodiment of the present invention, the resinous organohydrogen polysiloxane comprises a silicon atom-bonded hydrogen atom at the end of the molecule. This means that the resinous organohydrogen polysiloxane may comprise the silicon atom-bonded hydrogen atom at M siloxane units represented by (SiO_{1/2}). The resinous organohydrogen polysiloxane may or may not comprise alkenyl groups at D siloxane units represented by (SiO_{2/2}) and/or T units, however, it preferably does not comprise a silicon atom-bonded hydrogen atom at D nor T units.

In one embodiment of the present invention, the resinous organohydrogen polysiloxane as component (A2) may be present in an amount of 1% by weight or more, preferably 2% by weight or more, more preferably 3% by weight or more, and in particular 4% by weight or more, and may be present in an amount of 20% by weight or less, preferably 15% by weight or less, and more preferably 10% by weight or less, and even more preferably 7% by weight or less, relative to the total weight of the composition. Any combination of the upper limit and the lower limit is available.

In another embodiment of the present invention, the (A2) organohydrogen polysiloxane comprises at least one linear organohydrogen polysiloxane which can be represented by the following formula (II-b):

R⁴₂HSiO(R⁴₂SiO)ₘSiHR⁴₂ average structural formula (II-b):

in which, R⁴ indicates the same or different monovalent hydrocarbon other than an alkenyl group, which can be optionally substituted with at least one halogen; and m ranges from 1 to 50. One type of linear organohydrogen polysiloxane or two or more types of linear organohydrogen polysiloxane according to formula (II-b) can be used as the (A2) organohydrogen polysiloxane.

The same definition for the monovalent hydrocarbon as R³ in formula (II-a) can be applied to the monovalent hydrocarbon as R⁴ in formula (II-b).

In formula (II-b), m preferably ranges from 1 to 25, and more preferably from 1 to 10, and even more preferably ranges from 1 to 5.

In one preferred embodiment, the linear organohydrogen polysiloxane according to formula (II-b) comprises at least one aryl group, preferably a phenyl group, at side chain of the molecule chain. In other words, the linear organohydrogen polysiloxane according to formula (II-b) may comprise at least one aryl group at D siloxane units represented by (SiO_{2/2}). In another preferred embodiment, the linear organohydrogen polysiloxane according to formula (II-b) comprises at least one (Ar₂SiO_{2/2}) unit where Ar indicates an aryl group, preferably a phenyl group.

In one embodiment of the present invention, the linear organohydrogen polysiloxane according to formula (II-b) as component (A2) may be present in an amount of 2.5% by weight or more, preferably 5% by weight or more, more preferably 7.5% by weight or more, and in particular 10% by weight or more, and may be present in an amount of 35% by weight or less, preferably 30% by weight or less, and more preferably 25% by weight or less, and even more preferably 20% by weight or less, relative to the total weight of the composition. Any combination of the upper limit and the lower limit is available.

In another embodiment of the present invention, the (A2) organohydrogen polysiloxane comprises at least one linear organohydrogen polysiloxane which can be represented by the following formula (II-c):

R⁴₃SiO(R⁴HSiO)ₘSiR⁴₃ average structural formula (II-c):

in which, R⁴ indicates the same or different monovalent hydrocarbon other than an alkenyl group, which can be optionally substituted with at least one halogen; and m ranges from 1 to 200. One type of linear organohydrogen polysiloxane or two or more types of linear organohydrogen polysiloxane according to formula (II-c) can be used as the (A2) organohydrogen polysiloxane.

The same definition for the monovalent hydrocarbon as R³ in formula (II-a) can be applied to the monovalent hydrocarbon as R⁴ in formula (II-c).

In formula (II-c), m preferably ranges from 10 to 150, and more preferably from 20 to 100, and even more preferably ranges from 30 to 75.

The linear organohydrogen polysiloxane according to formula (II-c) may comprise or not comprise an aryl group. Preferably, the linear organohydrogen polysiloxane according to formula (II-c) does not comprise any aryl group. R₄ in formula (II-c) preferably indicates a C₁₋₁₂ alkyl group, in particular a methyl group.

In one embodiment of the present invention, the linear organohydrogen polysiloxane according to formula (II-c) as the component (A2) may be present in an amount of 0.5% by weight or more, preferably 1% by weight or more, more preferably 1.5% by weight or more, and in particular 2% by weight or more, and may be present in an amount of 15% by weight or less, preferably 10% by weight or less, and more preferably 7.5% by weight or less, and even more preferably 5% by weight or less, relative to the total weight of the composition. Any combination of the upper limit and the lower limit is available.

In another embodiment of the present invention, the (A2) organohydrogen polysiloxane comprises at least one organohydrogen polysiloxane in the form of MQ resin which can be represented by the following formula (II-d):

(R³₃SiO_{1/2})ₛ(SiO_{4/2})ₜ average structural formula (II-d):

in which, R³ indicates a hydrogen atom or the same or different monovalent hydrocarbon other than an alkenyl group, which can be optionally substituted with at least one halogen, wherein at least two of R³ per molecule represent hydrogen atoms; and 0<s<1, 0<t<1, and s+t=1.0 are satisfied.

The same definition for R³ in formula (II-a) can be applied to R³ in formula (II-d).

In one embodiment of the present invention, in formula (II-d), s preferably ranges from 0.25≤s≤0.8, more preferably in the range of 0.3≤s≤0.7, and even more preferably in the range of 0.35≤s≤0.65. In formula (I-b), t preferably ranges from 0.2≤t≤0.7, more preferably from 0.3≤t≤0.6, and even more preferably from 0.35≤t≤0.5.

In one embodiment of the present invention, the organohydrogen polysiloxane in the form of MQ resin according to formula (II-d) as the component (A2) may be present in an amount of 0.5% by weight or more, preferably 1% by weight or more, more preferably 1.5% by weight or more, and in particular 2% by weight or more, and may be present in an amount of 15% by weight or less, preferably 10% by weight or less, and more preferably 7.5% by weight or less, and even more preferably 5% by weight or less, relative to the total weight of the composition. Any combination of the upper limit and the lower limit is available.

In a case that the (A2) organohydrogen polysiloxane comprises aryl groups per molecule, the content of the aryl groups in the (A2) organohydrogen polysiloxane is not particularly limited, but in general 1 mol % or more, preferably 5 mol % or more, more preferably 10 mol % or more, and even more preferably 15 mol % or more, and in general 50 mol % or less, preferably 40 mol % or less, more preferably 30 mol % or less, even more preferably 25 mol % or less, relative to the total amount of the silicon atom-bonded functional groups. Any combination of the upper limit and the lower limit is available. The amount of the aryl groups can be measured, for example, with analytical methods such as Fourier transform infrared spectroscopy (FT-IR) or nuclear magnetic resonance (NMR), or the following titration method.

The (A2) organohydrogen polysiloxane may be present in an amount of 1% by weight or more, preferably 1.5% by weight or more, more preferably 2% by weight or more, and in particular 2.5% by weight or more, and may be present in an amount of 40% by weight or less, preferably 35% by weight or less, and more preferably 30% by weight or less, relative to the total weight of the composition. Any combination of the upper limit and the lower limit is available.

In one preferred embodiment of the present invention, the (A2) organohydrogen polysiloxane can be included in the composition so that the molar ratio of the silicon atom-bonded hydrogen atom derived from the component (A2) to alkenyl groups derived from the component (A1), i.e. H/Vi molar ratio, is 0.5 or more, preferably 0.6 or more, more preferably 0.7 or more, and even more preferably 0.75 or more; and may be 3.0 or less, preferably 2.0 or less, more preferably 1.7 or less, even more preferably 1.5 or less, and in particular 1.3 or less. Any combination of the upper limit and the lower limit is available.

### (A3) Hydrosilylation Catalyst

Component (A3) is a catalyst that promotes a hydrosilylation reaction. The composition according to the present invention may comprise one type of the (A3) hydrosilylation catalyst or may comprise two or more types of the (A3) hydrosilylation catalysts in combination.

Examples of the hydrosilylation catalyst include platinum based catalysts, rhodium based catalysts, palladium based catalysts, nickel based catalysts, iridium based catalysts, ruthenium based catalysts, and iron based catalysts. Platinum based catalysts are preferable. Examples of the platinum based catalyst include platinum based compounds, such as platinum fine powders, platinum black, platinum-supporting silica fine powders, platinum-supporting activated carbon, chloroplatinic acids, alcohol solutions of chloroplatinic acids, olefin complexes of platinum, alkenylsiloxane complexes of platinum, and the like. Alkenylsiloxane complexes of platinum are particularly preferable. Examples of the alkenylsiloxane include 1,3-divinyl-1,1,3,3-tetramethyldisiloxane, 1,3,5,7-tetramethyl-1,3,5,7-tetravinylcyclotetrasiloxane, alkenylsiloxanes having part of the methyl groups of these alkenylsiloxane substituted by ethyl groups, phenyl groups, or the like, and alkenylsiloxanes having vinyl groups of these alkenylsiloxane substituted by allyl groups, hexenyl groups, or the like.

The amount of the (A3) hydrosilylation catalyst used is an effective amount and is not particularly limited. For example, the (A3) hydrosilylation catalyst may be present in an amount of 0.1 ppm more, preferably 1 ppm or more, and more preferably 2 ppm or more, and may be present in an amount of 20 ppm or less, preferably 15 ppm or less, more preferably 10 ppm or less, and even more preferably 5 ppm or less, relative to the total weight of the (A) curing reactive organopolysiloxane. Any combination of the upper limit and the lower limit is available.

### (B) Inorganic Filler

The composition according to the present invention comprises at least one inorganic filler selected from silica, silica-titania composite oxide particle, alumina, clay, talc, and a combination thereof. One type of the (B) inorganic filler or two or more types of the (B) inorganic fillers may be used.

The (B) inorganic filler may have been subjected to surface hydrophobic treatment with an organosilicon compound such as an organoalkoxysilane compound, organochlorosilane compound, organosilazane compound, or low molecular weight siloxane compound, or silane coupling agent, titanate coupling agent or the like, before it is used in the present invention.

Examples of silica used as component (B) include fumed silica, wet silica, crystalline silica, precipitated silica, etc. Also, the silica may have been subjected to surface hydrophobic treatment with an organosilicon compound such as an organoalkoxysilane compound, organochlorosilane compound, organosilazane compound, or low molecular weight siloxane compound, or silane coupling agent, titanate coupling agent or the like.

The term “silica-titania composite oxide particle” here means a composite particle comprised of silica component (SiO₂) and a titanium oxide (TiO₂) component.

A refractive index of the silica-titania composite oxide particles is not particularly limited, but for example, its refractive index at 25° C. and at a wavelength of 589 nm is, for example, 1.40 or more, preferably 1.43 or more. More preferably 1.46 or more, and is usually 1.61 or less, preferably 1.58 or less, and more preferably 1.55 or less. Any combination of the upper limit and the lower limit is available.

As an example of a commercially available silica-titania composite oxide particle, which can be used in the present invention, mention can be made of, for example, silica-titania composite oxide particle sold by TOKUYAMA under the name of Sylfil® (specific surface area: 100 to 500 g/m², refractive index 1.48 to 1.54).

The composition ratio of the silica component and the titanium oxide component of the silica-titania composite oxide particle is not particularly limited, but for example, the content of titanium oxide component is 0.01 mol % or more and 25 mol % or less, and preferably 20 mol % or less. The content of the titanium component can be measured, for example, by fluorescent X-ray analysis. Any combination of the upper limit and the lower limit is available.

The (B) inorganic filler may have an average primary particle size of 5 nm or more, preferably 10 nm or more, more preferably 20 nm or more, and in particular 50 nm or more, and/or of 1 μm or less, preferably 700 nm or less, more preferably 500 nm or less, and in particular 300 nm or less. The term “average primary particle size” used herein represents a number-average size mean diameter which is given by the statistical particle size distribution to half of the population, referred to as D50. For example, the number-average size mean diameter can be measured by a laser diffraction particle size distribution analyzer.

The (B) inorganic filler is present in an amount of 1% by weight or more relative to the total weight of the composition. The (B) inorganic filler may be present in an amount of more than 1.5% by weight, preferably 3% by weight or more, and more preferably 4% by weight or more, and may be present in an amount of 30% by weight or less, preferably 20% by weight or less, and more preferably 15% by weight or less, and even more preferably 10% by weight or less, relative to the total weight of the composition. Any combination of the upper limit and the lower limit is available.

### (C) Additive

The composition according to the present invention comprises at least one additive selected from (C1) organopolysiloxane having at least one organic functional group including at least one polyether structure at molecular side chain and/or molecular terminal; (C2) organosilane compound comprising at least one organic functional group selected from a C₁-C₆ alkyl group, aryl group, and epoxy group; (C3) organopolysiloxane having at least one hydroxy group and at least one aryl group; (C4) organosiloxane oligomer having at least one epoxy group; (C5) at least one unsaturated carboxylic acid or an ester thereof; and combinations thereof.

The (C) additive can provide the composition according to the present invention with morphological stability at a high temperature, a long shelf-life, a high transparency, and/or an improved adhesion strength to substrates.

The (C) additive may be a silicone additive selected from components (C1) to (C4), and a combination thereof.

(C1) Side Chain and/or Terminal Polyether-Modified Organopolysiloxane

The (C1) organopolysiloxane is a side chain and/or terminal polyether-modified organopolysiloxane, more specific organopolysiloxane having at least one organic functional group including at least one polyether structure or at least one polyether unit at a molecular side chain and/or molecular terminal. In other words, the (C1) organopolysiloxane is an organopolysiloxane in which at least one side chain and/or molecular terminal is modified with at least one polyether structure or polyether unit.

The composition according to the present invention may comprise one type or two or more types of organopolysiloxane having at least one organic functional group including an ether bond at a molecular side chain and/or terminal.

The molecular structure of (C1) organopolysiloxane may be linear, branched, partially-branched, cyclic, or resinous, and is preferably linear.

In one embodiment of the present invention, the (C1) organopolysiloxane may be linear organopolysiloxane having at least one organic functional group including an ether bond at a molecular side chain, which can be represented by the following formula (c-1-1):

R⁵₃SiO(R⁵₂SiO)m(R⁵R⁶SiO)ₙSiR⁵₃ average structural formula (c-1):

in which, R⁵ indicates the same or different monovalent hydrocarbon other than an alkenyl group, which can be optionally substituted with at least one halogen; R⁶ indicates an organic group including a polyoxyalkylene group; m ranges from 0 to 1,000; and n ranges from 1 to 1,000.

In another embodiment of the present invention, the (C1) organopolysiloxane may be linear organopolysiloxane having at least one organic functional group including an ether bond at a molecular terminal, which can be represented by the following formula (c-1-2):

R⁶R⁵₂SiO(R⁵₂SiO)ₘSiR⁵₂R⁶ average structural formula (c-1-2):

in which, R⁵ indicates the same or different monovalent hydrocarbon other than an alkenyl group, which can be optionally substituted with at least one halogen; R⁶ indicates an organic group including a polyoxyalkylene group; m ranges from 0 to 1,000.

The monovalent hydrocarbon other than an alkenyl group for R⁵ in formula (c-1-1) and (c-1-2), which can be optionally substituted with at least one halogen, may include, C₁₋₁₂ alkyl groups such as methyl, ethyl, propyl, isopropyl, butyl, isobutyl, cert-butyl, pentyl, neopentyl, hexyl, cyclohexyl, heptyl, octyl, nonyl, decyl, undecyl and dodecyl groups; C₆₋₁₂ aryl groups such as phenyl, tolyl, xylyl and naphthyl groups; C₇₋₁₂ aralkyl groups such as benzyl, phenethyl, and phenylpropyl groups; and groups obtained by substituting some or all of the hydrogen atoms in these groups with halogen atoms such as fluorine, chlorine or bromine atoms. The monovalent hydrocarbon in R⁵ may include a small amount of hydroxy group or alkoxy group such as a methoxy or ethoxy group, provided that this does not adversely affect the aim of the present invention. Preferably, the monovalent hydrocarbon in R⁵ represents a C₁₋₁₂ alkyl group, in particular a methyl group.

The polyoxyalkylene group in the organic group of R⁶ in formula (c-1-1) and (c-1-2) may include two or more oxyethylene units, oxypropylene units, oxybutylene units, or a combination thereof. The polyoxyalkylene group preferably contains 4 or more, more preferably 6 or more, still more preferably 8 or more oxyalkylene units, and 100 or less, preferably 60 or less, more preferably 40 or less, even more preferably 20 or less oxyalkylene units. The alkylene part of the oxyalkylene group may be linear or branched. Any combination of the upper limit and the lower limit is available.

The organic group including a polyoxyalkylene group of R⁶ in formula (c-1-1) and (c-1-2) may be represented by the following formula (c-2):

—R⁷—O—(C₂H₄O)ₜ₁(C₃H₆O)ₜ₂(C₄H₈O)ₜ₃—Y General formula (c-2):

in which, R⁷ is a divalent organic group having 1 to 6 carbon atoms, preferably 1 to 3 carbon atoms, which is bonded to a silicon atom; 0≤t1≤60, 0≤t2≤50, 0≤t3≤50, and 2≤t1+t2+t3≤110 are satisfied; and Y is a group selected from a hydrogen atom, an alkyl group having 1 to 4 carbon atoms, and a COCH₃ group.

In general formula (c-2), R⁷ may represent, for example, an alkylene group, an alkenylene group, or an arylene group, and more specifically, for example, may represent methylene group, ethylene group, propylene group, butylene group, pentylene group, hexylene group, or phenylene group.

In general formula (c-2), Y is a terminal group having a polyoxyalkylene structure, and is selected from a hydrogen atom, an alkyl group having 1 to 4 carbon atoms, and a COCH₃ group, and preferably Y can be a hydrogen atom or a methyl group.

In general formula (c-2), t1, t2, and t3 are the number of oxyethylene units, oxypropylene units, and oxybutylene units constituting the polyoxyalkylene group, and 0≤t1+t2+t3≤110 is satisfied, and preferably 6≤t1+t2+t3≤50, more preferably 8≤t1+t2+t3≤20 is satisfied.

In one embodiment of the present invention, in formula (c-2), t1 is an integer of 2 or more, preferably 4 or more, more preferably 6 or more, even more preferably 8 or more, and is an integer of 50 or less, preferably 30 or less, more preferably 20 or less, and even more preferably 15 or less. In one embodiment of the present invention, in formula (c-2), t2 s an integer of 0 or more and 50 or less, preferably 30 or less, more preferably 10 or less, still more preferably 3 or less. In another embodiment, t2 can be 0. In one embodiment of the present invention, in formula (c-2), t3 is an integer of 0 or more and 50 or less, preferably 30 or less, more preferably 10 or less, still more preferably 3 or less. In another embodiment, t3 can be 0. Any combination of the upper limit and the lower limit is available.

In formula (c-1-1) and (c-1-2), n and m indicate a degree of siloxane polymerization of the (C1) linear organopolysiloxane having at least one organic functional group including an ether bond at a molecular side chain and/or terminal. Integer m ranges from 0 to 1000 and integer n ranges from 1 to 1000. Preferably, m is 1 or more and 500 or less, more preferably 150 or less, still more preferably 100 or less, even more preferably 50 or less, and particularly preferably 10 or less. Preferably, n is an integer ranging 500 or less, more preferably 150 or less, still more preferably 100 or less, even more preferably 50 or less, and particularly preferably 20 or less.

In one preferred embodiment, the (C1) linear organopolysiloxane having at least one organic functional group including an ether bond at a molecular side chain and/or terminal contains a polyoxyalkylene group selected from polyoxyethylene (POE), polyoxypropylene (POP), and a combination thereof. The (C1) linear organopolysiloxane can be preferably represented by the following general formula (c-3).

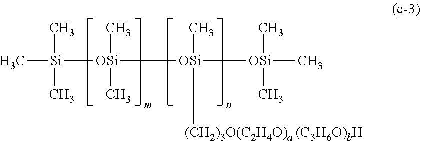

In the above general formula (c-3), m ranges from 1 to 1000, preferably from 5 to 500, and n ranges from 1 to 40. Also, a ratio m:n preferably ranges from 200:1 to 1:1. In addition, a ranges from 5 to 50, preferably from 8 to 30, and more preferably from 10 to 20, and b ranges from 0 to 50, preferably from 0 to 50, and more preferably from 0 to 10, and may be 0. That is, the polyether structure in the side chain and/or terminal of the (C1) organopolysiloxane may contain at least one polyoxyethylene unit and may comprise only at least one polyoxyethylene unit. In another embodiment, the polyether structure in the side chain and/or terminal of the (C1) organopolysiloxane contains at least one polyoxyethylene (POE) unit and at least one polyoxypropylene (POP) unit in combination.

In one preferred embodiment, the (C1) organopolysiloxane is selected from those having an HLB (Si) ranging from 4 to 15, preferably from 7 to 15, more preferably from 9 to 15, and even more preferably 11 to 15. The HLB (Si) referred to here is a value obtained by the following formula:

Molecular Weight of Polyoxyalkylene Group/Molecular Weight×20

Examples of the (C1) organopolysiloxane include PEG/PPG-19/19 dimethicone, PEG/PPG-30/10 dimethicone, PEG-12 dimethicone, and PEG-11 methyl ether dimethicone.

Commercially available examples of the (C1) organopolysiloxane include the following products:
Product name: BY11-030 (manufactured by Toray Dow Corning: PEG/PPG-19/19 dimethicone, HLB (Si)=7.7);
Product name SH3773M (manufactured by Toray Dow Corning: PEG-12 dimethicone, HLB (Si)=7.7);
Product name BY25-339 (manufactured by Toray Dow Corning: PEG/PPG-30/10 dimethicone, HLB (Si)=12.2);
Product name KF6011 (manufactured by Shin-Etsu Chemical: PEG-11 methyl ether dimethicone, HLB (Si)=14.5); and
Product name: EFKA® SL-3030 (manufactured by BASF: PEG/PPG ether modified dimethicone having a comb structure)
Product name: EFKA® SL3288 (manufactured by BASF: PEG/PPG ether-terminal modified linear dimethicone)

The number average molecular weights of the (C1) organopolysiloxane is not particularly limited, but may range from 3,000 to 60,000, and preferably from 3,000 to 40,000.

The (C1) organopolysiloxane may be present in an amount of 0.01% by weight or more, preferably 0.05% by weight or more, more preferably 0.08% by weight or more, and in particular 0.1% by weight or more, and may be present in an amount of 10% by weight or less, preferably 5% by weight or less, and more preferably 3% by weight or less, and even more preferably 1% by weight or less, relative to the total weight of the composition. Any combination of the upper limit and the lower limit is available.

### (C2) Organosilane Compound

The (C2) organosilane compound is an organosilane compound comprising at least one organic functional group selected from a C₁-C₆ alkyl group, aryl group, and epoxy group. One type or two or more types of the (C2) organosilane compounds may be used in combination.

The (C2) organosilane compound may be a mono-silane compound.

The organic functional group comprising at least one C₁-C₆ alkyl group may be liner or branched C₁-C₆ alkyl group, and preferably selected from methyl, ethyl, propyl, isopropyl, butyl, isobutyl, pentyl, neopentyl, and hexyl groups. Preferably, the C₁-C₆ alkyl group is selected from a methyl group, an ethyl group, and a propyl group.

The organic functional group comprising at least one aryl group may be selected from C₆₋₁₂ aryl groups such as phenyl, tolyl, xylyl, and naphthyl groups, and C₇₋₁₂ aralkyl groups such as benzyl, phenethyl, and phenylpropyl groups.

The organic functional group comprising at least one epoxy group may be selected from glycidoxyalkyl groups, such as 2-glycidoxyethyl group, 3-glycidoxypropyl group, and 4-glycidoxybutyl group; epoxycycloalkyl groups, such as 2-(3,4-epoxycyclohexyl) ethyl group, 3-(3,4-epoxycyclohexyl)-propyl group; or epoxyalkyl groups, such as 3,4-epoxybutyl group and 7,8-epoxyoctyl group.

The (C2) organosilane compound may include one or two or more organic functional groups selected from C₁-C₆ alkyl group, aryl group, and epoxy group per molecule. In one embodiment of the present invention, the (C2) organosilane compound comprises one organic functional group selected from C1-C₆ alkyl group, aryl group, or epoxy group per molecule.

In one preferred embodiment of the present invention, the (C2) organosilane compound does not include any ethylenically unsaturated groups including alkenyl groups, such as a vinyl group, and (meth)acryl groups. In another preferred embodiment of the present invention, the (C2) organosilane compound does not include any alkyl groups having 7 or more carbon atoms.

In one embodiment of the present invention, the (C2) organosilane compound may be represented by the following formula: R_{(4-b)}SiX_{b}

wherein R indicates the same or different organic functional groups including at least one C₁-C₆ alkyl group, aryl group, and/or epoxy group; and X indicates the same or different alkoxy groups such as a methoxy group, an ethoxy group, and a propoxy group; oxime groups such as an acetooxime group and a methylethylketoxime group; amino groups such as a dimethylamino group and a diethylamino group; amide groups such as an N-methylacetamide group; aminooxy groups such as a diethylaminooxy group; and alkenyloxy groups such as an isopropenyloxy group; and b is 1, 2, or 3, and preferably 2 or 3, and more preferably 3.

X in the above formulae is preferably selected from alkoxy groups, preferably C₁-C₆ alkoxy groups, such as a methoxy group, an ethoxy groups, and a propoxy group.

The (C2) organosilane compound can be a silane coupling agent. Examples of the (C2) organosilane compound includes methyltrimethoxysilane, ethyltrimethoxysilane, propyltrimethoxysilane, butyltrimethoxysilane, methyltriethoxysilane, ethyltriethoxysilane, propyltriethoxysilane, butyltriethoxysilane, phenyl trimethoxysilane, 3-glycidoxypropyltrimethoxysilane, 3-glycidoxypropyltriethoxycisilane, 3-glycidoxypropylmethyldimethoxysilane, 3-glycidoxypropylmethyldiethoxysilane, glycidyloxypropyl (dimethoxy)methylsilane, glycidyloxypropyl (trimethoxy)silane, 2-(3,4-epoxy) cyclohexyl) ethyltrimethoxysilane, N-phenylaminomethyltrimethoxysilane, and N-phenylaminopropyltrimethoxysilane.

The (C2) organosilane compound may not be covalently bound to the surface of the (B) inorganic fillers substantively. The (C2) organosilane compound is therefore not intended to be used as a surface-treating agent which is a common use for a silane coupling agent. The (C2) organosilane compound is different from organosilane compounds which is intended to be covalently bound to the surface of the inorganic filler. For example, the (C2) organosilane compound may not be covalently bound to the surface of the (B) inorganic fillers substantively because the surface of the (B) inorganic fillers has been surface-treated with another surface-treatment agent in advance.

The use of the (C2) organosilane compound in the composition of the present invention is preferable since it is possible to provide the composition with longer shelf life as well as improved adhesive property.

The (C2) organosilane compound may be present in an amount of 0.01% by weight or more, preferably 0.05% by weight or more, more preferably 0.1% by weight or more, and in particular 0.2% by weight or more, and may be present in an amount of 5% by weight or less, preferably 3% by weight or less, and more preferably 2% by weight or less, and even more preferably 1% by weight or less, relative to the total weight of the composition. Any combination of the upper limit and the lower limit is available.

### (C3) Organopolysiloxane Having at Least One Hydroxy Group and at Least One Aryl Group

One type or two or more types of the (C3) organopolysiloxane having at least one hydroxy group and at least one aryl group may be used in combination.

The molecular structure of (C3) organopolysiloxane may be linear, branched, partially-branched, cyclic, or resinous, and is preferably linear or resinous.

The (C3) organopolysiloxane comprises at least one hydroxy group. The (C3) organopolysiloxane preferably comprises at least one hydroxy group bound to a silicon atom, i.e. SiOH group.

The (C3) organopolysiloxane also comprises at least one aryl group bound to a silicon atom. The aryl group may be C₆₋₁₂ aryl groups such as phenyl, tolyl, xylyl and naphthyl groups, and preferably a phenyl group.

Other silicon atom-bonded organic functional groups other than the hydroxy group and the aryl group included in component (C3) may include C₁₋₁₂ alkyl groups such as methyl, ethyl, propyl, isopropyl, butyl, isobutyl, cert-butyl, pentyl, neopentyl, hexyl, cyclohexyl, heptyl, octyl, nonyl, decyl, undecyl and dodecyl groups; C₂₋₁₂ alkenyl groups, such as a vinyl, allyl, butenyl, pentenyl, hexenyl, heptenyl, octenyl, nonenyl, decenyl, undecenyl, and dodecenyl groups; and preferably a vinyl group: C₇₋₁₂ aralkyl groups such as benzyl, phenethyl, and phenylpropyl groups; and groups obtained by substituting some or all of the hydrogen atoms in these groups with halogen atoms such as fluorine, chlorine or bromine atoms. Preferably, the silicon atom-bonded organic functional groups other than hydroxy groups and aryl groups comprise a C₁₋₁₂ alkyl group, in particular a methyl group, and a C₂₋₁₂ alkenyl group, in particular a vinyl group. Component (C3) may not include any thiol groups nor any epoxy groups.

In one embodiment of the present invention, the (C3) organopolysiloxane further comprises at least one alkenyl group, such as a vinyl group. In one preferred embodiment of the present invention, the (C3) organopolysiloxane comprises at least one silicon atom-bonded hydroxy group, at least one silicon atom-bonded aryl group, and at least one silicon atom-bonded alkenyl group, such as a vinyl group.

In one embodiment of the present invention, the (C3) hydroxy and aryl group-containing organopolysiloxane is resinous organopolysiloxane which can be represented by the following formula (c-4):

(R¹₃SiO_{1/2})ₐ(R¹₂SiO_{2/2})_{b}(R¹SiO_{3/2})_{c}(SiO_{4/2})_{d}(HO_{1/2})ₑ(XO_{1/2})_{f} average unit formula (c-4):

in which, R¹ indicates the same or different monovalent hydrocarbon, which can be optionally substituted with at least one halogen, wherein at least one of R¹ per molecule represents an aryl group; X represents an alkyl group; and 0≤a<1, 0≤b<1, 0≤c<0.95, 0≤d<0.9, 0≤e<0.4, 0≤f<0.4, a+b+c+d=1.0, and c+d>0 are satisfied. One type of resinous organopolysiloxane or two or more types of resinous organopolysiloxane can be used as the (C3) hydroxy group-containing organopolysiloxane.

In another embodiment of the present invention, the (C3) hydroxy and aryl group-containing organopolysiloxane is linear organopolysiloxane which can be represented by the following formula (c-5):

R¹₃SiO(R¹₂SiO)ₘSiR⁵₃ average structural formula (c-5):

in which, R¹ indicates the same or different monovalent hydrocarbon, which can be optionally substituted with at least one halogen, wherein at least one of R¹ per molecule represents a hydroxy group and at least one of R¹ per molecule represents an aryl group; and m ranges from 1 to 100, preferably 1 to 50, and more preferably 1 to 20.

In yet another embodiment of the present invention, the (C3) hydroxy and aryl group-containing organopolysiloxane comprises at least one hydroxy group at a molecular terminal. In yet another embodiment of the present invention, the (C3) hydroxy and aryl group-containing organopolysiloxane comprises at least one aryl group at a molecular side chain. Thus, the (C3) hydroxy and aryl group-containing organopolysiloxane can be represented by the following formula (c-5′):

(HO)R¹₂SiO(ArR¹SiO)ₘSiR¹₂(OH) average structural formula (c-5′):

in which, R¹ indicates the same or different monovalent hydrocarbon, which can be optionally substituted with at least one halogen, Ar represents an aryl group; and m ranges from 1 to 100, preferably 1 to 50, and more preferably 1 to 20.

The monovalent hydrocarbon for R¹ in formulae (c-4) and (c-5), which can be optionally substituted with at least one halogen, may be the same as those explained as the silicon atom-bonded functional groups for component (C3).

The amount of the hydroxy groups relative to the total amount of the silicon atom-bonded functional groups in the (C3) organopolysiloxane is not particularly limited, but for example 0.1 mol % or more, preferably 0.5 mol % or more, more preferably 1 mol % or more, and even more preferably 2 mol % or more, and in general 30 mol % or less, preferably 20 mol % or less, more preferably 10 mol % or less, and even more preferably 5 mol % or less, relative to the total amount of the silicon atom-bonded functional groups. The amount of the hydroxy groups can be measured, for example, with analytical methods such as Fourier transform infrared spectroscopy (FT-IR) or nuclear magnetic resonance (NMR).

The (C3) organopolysiloxane having at least one hydroxy group may be present in an amount of 0.01% by weight or more, preferably 0.05% by weight or more, more preferably 0.1% by weight or more, and in particular 0.2% by weight or more, and may be present in an amount of 20% by weight or less, preferably 15% by weight or less, and more preferably 10% by weight or less, and even more preferably 5% by weight or less, relative to the total weight of the composition. Any combination of the upper limit and the lower limit is available.

### (C4) Organosiloxane Oligomer Having at Least One Epoxy Group

One type or two or more types of the (C4) organosiloxane oligomer having at least one epoxy group may be used in combination.

The (C4) organosiloxane oligomer may comprise 2 to 20 siloxane units, preferably 3 to 18 siloxane units, and more preferably 3 to 15 siloxane units.

The organosiloxane oligomer may be linear, branched, partially-branched, cyclic, or resinous. In one embodiment, the organosiloxane oligomer is resinous organosiloxane oligomer.

The (C4) organosiloxane oligomer comprises at least one epoxy group. The epoxy group included in (C4) organosiloxane oligomer may be selected from glycidoxyalkyl groups, such as 2-glycidoxyethyl group, 3-glycidoxypropyl group, and 4-glycidoxybutyl group; epoxycycloalkyl groups, such as 2-(3,4-epoxycyclohexyl) ethyl group, 3-(3,4-epoxycyclohexyl)-propyl group; or epoxyalkyl groups, such as 3,4-epoxybutyl group and 7,8-epoxyoctyl group.

Other silicon atom-bonded organic functional groups other than an epoxy group included in component (C4) may include C₁₋₁₂ alkyl groups such as methyl, ethyl, propyl, isopropyl, butyl, isobutyl, cert-butyl, pentyl, neopentyl, hexyl, cyclohexyl, heptyl, octyl, nonyl, decyl, undecyl and dodecyl groups; C₂₋₁₂ alkenyl groups, such as a vinyl, allyl, butenyl, pentenyl, hexenyl, heptenyl, octenyl, nonenyl, decenyl, undecenyl, and dodecenyl groups; and preferably a vinyl group: C₆₋₁₂ aryl groups such as phenyl, tolyl, xylyl and naphthyl groups; C₇₋₁₂ aralkyl groups such as benzyl, phenethyl, and phenylpropyl groups; and groups obtained by substituting some or all of the hydrogen atoms in these groups with halogen atoms such as fluorine, chlorine or bromine atoms. Preferably, the silicon atom-bonded functional groups other than hydroxy groups comprise a C1-12 alkyl group, in particular a methyl group, and a C₂₋₁₂ alkenyl group, in particular a vinyl group. Component (C4) may not include any thiol groups.

In one preferred embodiment of the present invention, the (C4) organosiloxane oligomer comprises at least one epoxy group and at least one alkenyl group, such as a vinyl group.

In one embodiment of the present invention, the (C4) organosiloxane oligomer is resinous organosiloxane oligomer which can be represented by the following formula (c-6):

(R¹₂SiO_{2/2})ₐ(R¹SiO_{3/2})_{b}(SiO_{4/2})_{c}(XO_{1/2})_{d} average unit formula (c-6):

in which, R¹ indicates the same or different monovalent hydrocarbon, which can be optionally substituted with at least one halogen, wherein at least one of R¹ per molecule represents an epoxy group; X represents an alkyl group; and 0≤a<1, 0≤b<1, 0≤c<0.95, 0≤d<0.4, a+b+c=1.0, and b+c>0 are satisfied.

The monovalent hydrocarbon for R¹ in formula (c-6), which can be optionally substituted with at least one halogen, may be the same as those explained as the silicon atom-bonded functional groups for component (C4).

In one embodiment of the present invention, in formula (c-6), a ranges preferably from 0.1≤a≤0.9, more preferably in the range of 0.3≤a≤0.8, and even more preferably in the range of 0.5≤a≤0.7. In formula (c-6), b ranges preferably from 0.05≤b≤0.6, more preferably from 0.1≤b≤0.5, and even more preferably from 0.15≤b≤0.4. In formula (c-6), c ranges preferably from 0≤c≤0.5, more preferably from 0≤c≤0.3, and even more preferably from 0≤c≤0.1. In formula (c-6), d ranges preferably from 0≤d≤0.2, more preferably from 0≤d≤0.1, and even more preferably from 0≤d≤0.05.

In one embodiment of the present invention, the (C4) organosiloxane oligomer does not include M siloxane unit represented by (SiO_{1/2}). In another embodiment of the present invention, in formula (c-6), b is more than 0, i.e., the (C4) organosiloxane oligomer comprises at least one T siloxane unit represented by (SiO_{3/2}). The (C4) organosiloxane oligomer mayor may not comprise a Q siloxane unit represented by (SiO_{4/2}), however, it preferably does not comprise any Q units. In another embodiment of the present invention, in formula (c-6), d is more than 0, i.e., the (C4) organosiloxane oligomer comprises at least one —OR group bound to a silicon atom.

In another embodiment of the present invention, the (C4) organosiloxane oligomer is a condensation reaction product of organosilane compounds including at least one (C2) organosilane compound comprising at least one epoxy group as explained above. The condensation reaction product can be derived from one type of the organosilane compound, or two or more type of the organosilane compounds. In other word, the (C4) organosiloxane oligomer may comprise at least one unit derived from the (C2) organosilane compound comprising at least one epoxy group.

The condensation reaction can be a hydrolysis condensation reaction. Thus, the (C4) organosiloxane oligomer can be a hydrolysis condensation reaction product.

The degree of the condensation reaction of the condensation reaction is not particularly limited, but can be 2 to 20, preferably 3 to 15 siloxane units, and more preferably 3 to 10.

In one specific embodiment of the present invention, the (C4) organosiloxane oligomer is a condensation reaction product of 2 to 20 of glycidoxypropyltrimethoxysilanes, 3-glycidoxypropyltriethoxycisilanes, 3-glycidoxypropylmethyldimethoxysilanes, 3-glycidoxypropylmethyldiethoxysilanes, glycidyloxypropyl (dimethoxy)methylsilanes, glycidyloxypropyl (trimethoxy)silanes, 2-(3,4-epoxy)cyclohexyl)ethyltrimethoxysilanes, glycidyloxypropyl (trimethoxy)silanes, and any combination thereof, and in particular a condensation reaction product of four glycidyloxypropyl (trimethoxy)silanes.

In yet another embodiment of the present invention, the (C4) organosiloxane oligomer is a condensation reaction product of at least one (C2) organosilane compound comprising at least one epoxy group with at least one organosilane compound or oligomer thereof comprising at least one organic functional group other than an epoxy group. In one embodiment, the (C4) organosiloxane oligomer is a condensation reaction product of at least one (C2) organosilane compound comprising at least one epoxy group with at least one organosilane compound or oligomer thereof comprising ethylenically unsaturated groups including alkenyl groups, such as a vinyl group.

In yet another embodiment of the present invention, the (C4) organosiloxane oligomer is a condensation reaction product of organosiloxane oligomer having vinyl group and capped at both molecular terminals with silanol groups and 3-glycidoxypropyl trimethoxysilane.

The amount of the epoxy groups relative to the total amount of the silicon atom-bonded functional groups in the (C4) organopolysiloxane is not particularly limited, but for example 3 mol % or more, preferably 5 mol % or more, and more preferably 10 mol % or more, and in general 50 mol % or less, preferably 40 mol % or less, more preferably 30 mol % or less, relative to the total amount of the silicon atom-bonded functional groups. Any combination of the upper limit and the lower limit is available. The amount of the epoxy groups can be measured, for example, with analytical methods such as Fourier transform infrared spectroscopy (FT-IR) or nuclear magnetic resonance (NMR).

The (C4) organosiloxane oligomer having at least one epoxy group may be present in an amount of 0.01% by weight or more, preferably 0.05% by weight or more, more preferably 0.1% by weight or more, and in particular 0.2% by weight or more, and may be present in an amount of 25% by weight or less, preferably 20% by weight or less, and more preferably 15% by weight or less, and even more preferably 10% by weight or less, relative to the total weight of the composition. Any combination of the upper limit and the lower limit is available.

### (C5) Unsaturated Carboxylic Acid or an Ester Thereof

One type or two or more types of the (C5) unsaturated carboxylic acids or esters thereof may be used in combination.

The (C5) unsaturated carboxylic acid may be an ethylenically unsaturated carboxylic acid. The (C5) unsaturated carboxylic acid may be selected from C₄₋₈ unsaturated carboxylic acid, such as acrylic acid, methacrylic acid, ethacrylic acid, itaconic acid, fumaric acid, crotonic acid, and maleic acid.

The (C5) unsaturated carboxylic acid ester may be an alkyl ester of the (C5) unsaturated carboxylic acid. The (C5) unsaturated carboxylic acid ester may be alkyl (meth)acrylates, such as methyl acrylate, ethyl acrylate, isobutyl acrylate,-butyl acrylate, isooctyl acrylate, methyl methacrylate, ethyl methacrylate, isobutyl methacrylate,-butyl methacrylate, dimethyl maleate, and diethyl maleate.

In one embodiment, the (C5) unsaturated carboxylic acid ester may be selected from unsaturated carboxylic acid alkyl esters wherein the alkyl group has from 1 to 12 carbon atoms, for example, alkyl acrylates, such as methyl acrylate, ethyl acrylate, isobutyl acrylate, n-butyl acrylate, and isooctyl acrylate; alkyl methacrylates, such as methyl methacrylate, ethyl methacrylate, and isobutyl methacrylate; and alkyl maleates, such as dimethyl maleate and diethyl maleate.

The (C5) unsaturated carboxylic acid ester may be preferably selected from C₁₋₄ alkyl ester of the (C5) unsaturated carboxylic acid, such as methyl acrylate, ethyl acrylate, isobutyl acrylate, n-butyl acrylate, methyl methacrylate, ethyl methacrylate, isobutyl methacrylate, n-butyl methacrylate, dimethyl maleate, diethyl maleate, and the like.

The (C5) unsaturated carboxylic acid(s) or ester(s) thereof may be present in an amount of 0.01% by weight or more, preferably 0.02% by weight or more, and more preferably 0.05% by weight or more, and may be present in an amount of 3% by weight or less, preferably 1% by weight or less, and more preferably 0.5% by weight or less, relative to the total weight of the composition. Any combination of the upper limit and the lower limit is available.

### (Other Ingredients)

The curable silicone composition may comprise a hydrosilylation-reaction inhibitor as an additional component. One type of the hydrosilylation-reaction inhibitor or two or more types of hydrosilylation-reaction inhibitors may be used.

As the hydrosilylation-reaction inhibitor, mention can be made of acetylenic alcohols such as methyl butynol, ethynyl cyclohexanol, dimethyl hexynol, 3,5-dimethyl-1-hexyn-3-ol, 1-butyn-3-ol, 1-propyn-3-ol, 2-methyl-3-butyn-2-ol, 3-methyl-1-butyn-3-ol, 3-methyl-1-pentyn-3-ol, 3-phenyl-1-butyn-3-ol, 4-ethyl-1-octyn-3-ol, 1-ethynyl-1-cyclohexanol, and combinations thereof; cycloalkenylsiloxanes such as methylvinylcyclosiloxanes exemplified by 1,3,5,7-tetramethyl-1,3,5,7-tetravinylcyclotetrasiloxane, 1,3,5,7-tetramethyl-1,3,5,7-tetrahexenylcyclotetrasiloxane, and a combination thereof; ene-yne compounds such as 3-methyl-3-penten-1-yne, 3,5-dimethyl-3-hexen-1-yne; triazoles such as benzotriazole; phosphines; mercaptans; hydrazines; amines, such as tetramethyl ethylenediamine, dialkyl fumarates, dialkenyl fumarates, dialkoxyalkyl fumarates, maleates such as diallyl maleate; nitriles; ethers; carbon monoxide; alkenes such as cyclo-octadiene, divinyltetramethyldisiloxane; alcohols such as benzyl alcohol; and a combination thereof. Alternatively, the hydrosilylation-reaction inhibitor may be selected from a group consisting of acetylenic alcohols (e.g., 1-ethynyl-1-cyclohexanol) and maleates (e.g., diallyl maleate, bis maleate, or n-propyl maleate) and a combination of two or more thereof.

The amount of the hydrosilylation-reaction inhibitor present in the curable silicone composition may be 0% to 5% by weight, preferably 0.001% to 3% by weight, and more preferably 0.005% to 1% by weight, relative to the total weight of the composition.

The curable silicone composition according to the present invention may also comprise any optional additive(s) usually used in the field, chosen, for example, from organopolysiloxanes other than components (A) and (C) above, organic fillers, inorganic fillers other than the component (B) above, pigments, adhesion-imparting agents, resistance imparting agent, releasing agents, heat resistance agents, dyes, flame retardancy imparting agents, and mixtures thereof.

In a certain embodiment of the present invention, the curable silicone composition comprises inorganic fillers other than the component (B), such as titanium dioxide and alumina, in an amount of less than 30% by weight, preferably less than 20% by weight, more preferably less than 10% by weight, even more preferably less than 3% by weight, and in particularly preferably less than 1% by weight, relative to the total weight of the composition,

The curable silicone composition according to the present invention can be prepared by mixing the above-described essential and optional components in a conventional manner. The mixing method of each components can be conducted with a conventionally known method and is not particularly limited. For example, the mixing is carried out by simple stirring or mixing using a mixing device, such as a uniaxial or biaxial continuous mixer, a double roll, a Hobart mixer, a dental mixer, a planetary mixer, a kneader mixer, and a Henschel mixer.

The curable silicone composition according to the present invention may have a viscosity ranging from 3 to 80 Pa·s, preferably from 5 to 50 Pa·s, and more preferably from 10 to 40 Pa·s, and even more preferably from 12 to 30 Pa-s at 25° C. The viscosity herein can be measured with a rheometer from Antonpaar with 40 mm cone plate at 2 degree angle at a shear rate of 10/s.

The curable silicone composition according to the present invention can be cured to form a cured product having good transparency. Specifically, the cured product of the curable silicone composition of the present invention preferably has a light transmittance of 30% or more, more preferably 50% or more, and 70% or more at a wavelength of 400 nm to 700 nm, for example, at 450 nm. The light transmittance of the cured product can be determined, for example, by measuring the cured product having an optical path length of 1 with a spectrophotometer.

The curable silicone composition according to the present invention can be used to encapsulate or seal a semiconductor element including an optical semiconductor in manufacturing semiconductor devices. In this embodiment, the curable silicone composition can be applied to a substrate, for example, selected from a glass substrate and PCB substrate. The glass substrate may be surface-coated or not coated with a well-known surface treatment agent, such as silicone surface treatment agents.

### [Sealing Material]

The present invention also relates to a sealing material obtained by curing the curable silicone composition according to the present invention. The sealing material of the present invention is preferably used for sealing a semiconductor element including an optical semiconductor. The shape of the sealing material is not limited, but preferably is a dome shape, a lens shape, or a sheet form. Examples of the semiconductor element include SiC, GaN, and the like. Examples of the optical semiconductor element include elements represented by light-emitting diodes (LEDs), photo diodes, photo transistors, laser diodes, and the like.

The substrate on which the sealing material of the present invention is formed, is not particularly limited, but, for example, the substrate may be selected from a glass substrate and PCB substrate. The glass substrate may be surface-coated or not coated with a well-known surface treatment agent, such as silicone surface treatment agents.

### [Optical Semiconductor Device]

The present invention also relates to an optical semiconductor device provided with the sealing material of the present invention. Examples of the optical semiconductor element include a light emitting diode (LED), a semiconductor laser, a photodiode, a phototransistor, a solid-state imaging device, and a light emitting body and a light receiving body for a photocoupler, and a light emitting diode (LED) is particularly preferable.

Since the light emitting diode (LED) emits light from the top, bottom, left, and right of the optical semiconductor element, it is preferable that the parts constituting the light emitting diode (LED) have a high light transmittance. As the substrate on which such an optical semiconductor element is mounted, mention can be made of conductive metals such as silver, gold, and copper; non-conductive metals such as aluminum and nickel; thermoplastic resins, containing white pigments, such as PPA and LCP; thermosetting resins containing white pigments, such as epoxy resins, BT resins, polyimide resins, and silicone resins; ceramics such as alumina and alumina nitride.

### Examples

The present invention will be described in more detail by way of examples which however should not be construed as limiting the scope of the present invention.

The curable silicone compositions of the present invention will be described in detail by examples and comparative examples. In the examples and comparative examples, the following components were used to prepare the curable silicone compositions. In the formulae, Vi indicates a vinyl group, Me indicates a methyl group, Ph indicates a phenyl group, and Ep indicates a 3-glycidoxypropyl group. In addition, the chemical formula of the organopolysiloxane component is shown in a simplified manner in the table, and the functional groups other than Me in M, D, or T units are shown in parentheses. The numerical values for the amounts of the components shown in the tables are all based on “part by weight” as active raw materials.

Components:
(a-1) alkenyl group-containing resinous organopolysiloxane represented by the formula (Me₃SiO_{1/2})_{0.14}(Me₂ViSiO_{1/2})_{0.11}(MeSiO_{3/2})_{0.53}(PhSiO_{3/2})_{0.22}
(a-2) alkenyl group-containing linear organopolysiloxane represented by the formula: ViMe₂SiO(Me₂SiO_{2/2})₆₀(Ph₂SiO_{2/2})₃₀SiMe₂Vi
(a-3) alkenyl group-containing cyclic organopolysiloxane represented by the formula (MeViSiO)₄
(a-4) alkenyl group and epoxy group-containing resinous organopolysiloxane represented by the formula (Me₃SiO_{1/2})_{0.13}(MeEpSiO_{2/2})_{0.24}(PhSiO₃₂)_{0.46}(OMe)_{0.17}
(a-5) alkenyl group-containing resinous organopolysiloxane represented by the formula (Me₃SiO_{1/2})_{0.05}(Me₂ViSiO_{1/2})_{0.17}(MeSiO_{3/2})_{0.39}(PhSiO₃₂)_{0.39}
(a-6) alkenyl group-containing resinous organopolysiloxane represented by the formula (Me₂ViSiO_{1/2})_{0.75}(PhSiO_{3/2})_{0.25}
(a-7) alkenyl group-containing linear organopolysiloxane represented by the formula: ViMe₂SiO(MePhSiO_{2/2})₂₀SiMe₂Vi
(a-8) alkenyl group-containing linear organopolysiloxane represented by the formula: ViMe₂SiO(Me₂SiO_{2/2})₅₃₀SiMe₂Vi
(a-9) alkenyl group-containing resinous organopolysiloxane represented by the formula (Me₃SiO_{1/2})_{0.34}(Me₂ViSiO_{1/2})_{0.11}(SiO₄₂)_{0.55}
(a-10) alkenyl group-containing linear organopolysiloxane represented by the formula: ViMe₂SiO(Me₂SiO_{2/2})₁₅₀SiMe₂Vi
(a-11) alkenyl group-containing resinous organopolysiloxane represented by the formula (Me₂ViSiO_{1/2})_{0.25}(PhSiO₃₂)_{0.75}
(a-12) alkenyl group-containing resinous organopolysiloxane represented by the formula (Me₃SiO_{1/2})_{0.45}(Me₂ViSiO_{1/2})_{0.15}(SiO_{4/2})_{0.40} (Mw: 1100)
(b-1) linear organohydrogen polysiloxane represented by the formula HMe₂SiO(Ph₂SiO_{2/2})SiMe₂H
(b-2) resinous organohydrogen polysiloxane represented by the formula (Me₂HSiO_{1/2})_{0.6}(PhSiO_{3/2})_{0.4}
(b-3) linear organohydrogen polysiloxane represented by the formula Me₃SiO(MeHSiO_{2/2})₅₀SiMe₃
(b-4) resinous organohydrogen polysiloxane represented by the formula (Me₃SiO_{1/2})_{0.002}(Me₂HSiO_{1/2})_{0.6}(SiO_{4/2})_{0.398} (Mw: 1638)
(c-1) fumed silica (average primary particle size: <30 nm)
(c-2) silica-titania composite oxide particle (Product name: SILFIL® sold by TOKUYAMA)
(d-1) side chain polyether-modified organopolysiloxane represented by the formula Me₃SiO(Me₂SiO)ₙ(Me(POE)SiO)ₘSiMe₃ (Product name KF6011 sold by Shin-Etsu Chemical, HLB (Si)=14.5)
(d-2) side chain polyether-modified organopolysiloxane represented by the formula Me₃SiO(Me₂SiO)ₙ(Me(POE)(POP)RSiO)ₘSiMe₃ (Product name EFKA® SL-3030 sold by BASF)
(d-3) PO—OH terminated linear polyether-modified organopolysiloxane represented by the formula HO—(PO)ₘ-(EO)_{m′}-(Me₂SiO)ₙ-(EO)_{m′}—(PO)ₘ—OH (Product name EFKA® SL-3288 sold by BASF)
(d-4) Phenyl trimethoxysilane
(d-5) Methyl trimethoxysilane
(d-6) 3-Glycidoxypropyl trimethoxysilane
(d-7) 3-Glycidoxypropyl triethoxysilane
(d-8) condensation reaction product of methylvinylsiloxane oligomer capped at both molecular terminals with silanol groups and 3-glycidoxypropyl trimethoxysilane (average Mw: 1280, viscosity of 22.5 mm²/s), represented by (EpSiO_{3/2})ₐ(MeViSiO_{2/2})_{b}(Me₂SiO_{2/2})_{c}(OR)_{d}
(d-9) 3-Glycidoxypropyl (dimethoxy)methylsilane
(d-10) M(Vi)₂₅-T(Ph)₇₅-OH (SiOH content is over 2.7 mol %)
(d-11) Acrylic acid aqueous solution (12% in aq.)
(d-12) condensation reaction product of 3-glycidyloxypropyl (trimethoxy)silanes
(d-13) Hydroxy terminated linear organopolysiloxane represented by the formula HO(PhMeSiO)ₙH: n=2 to 8
(d′-1) Methacryl trimethoxy silane
(d′-2) Octyl trimethoxysilane
(d′-3) Vinyl trimethoxysilane
(e-1) 1-ethyneyl-1-cyclohexanol
(e-2) bis maleate
(f) complex of platinum and 1,3-divinyl-1,1,3,3-tetramethyldisiloxane (platinum concentration: 3.0% by weight)

### [Evaluation]

(Viscosity and Thixotropic property)

The viscosity of the prepared curable silicone composition of each of the examples was measured with a rheometer (Antonpaar MCR302) with 40 mm cone plate at 2 degree angle at a shear rate of 10/s and 1/s at 25° C. Thixotropic index was calculated as a viscosity ratio of (viscosity at 1/s)/(viscosity at 10/s). Also, a change of a viscosity after storage at 50° C. for 30 days to determine a pot-life of the composition, i.e., the smaller viscosity change after the storage is, the longer pot-life the composition has.

### (Refractive Index)

A refractive index of the curable silicone composition at 25° C. was measured with an Abbe type refractive index meter at a wave length of 589 nm.

### (Morphological Analysis)

The curable silicone composition was dispensed on a glass substrate or a PCB substrate so as to form a straight line shape having a height of about 1 mm. After leaving the composition for 3 hours at 25° C., the dispensed curable silicone composition was then cured at 150° C. for 60 minutes. The height and width of the line-shaped composition was measured using an optical microscope just after the application, i.e., before curing, and after curing to determine an aspect ratio of the line (a height of the line/a width of the line). A change (%) of the aspect ratio between before and after curing was calculated.

It can be said that the higher dome aspect ratio after cure is, the more stable the dome shape is. Also, it can be said that the lower change (%) is, the more stable the shape is.

### (Die Share Strength)

The curable silicone composition was applied to a PCB substrate or glass substrate. The composition was cured at 150° C. for 2 hours. The die share strength was measured with a die-share tester (DAGE4000 plus bond tester manufactured by Nordson DAGE).

### (Transmittance)

The curable silicone composition was filled into a mold having a concavity with a predetermined shape and was then cured at 150° C. for 60 minutes. The obtained plate-like cured product having a thickness of 1 mm was subjected to transmittance measurement at 450 nm at 25° C.

The results are summarized in the tables below.

TABLE 1

| | | | | | | | Comp. |
|---|---|---|---|---|---|---|---|
| | Ex. 1 | Ex. 2 | Ex. 3 | Ex. 4 | Ex. 5 | Ex.6 | Ex. 1 |
| Components | | | | | | | |
| a-1 M₁₄—M(Vi)₁₁—T₅₃—T(Ph)₂₂ | 60.9 | 60.9 | 60.9 | 60.9 | 60.9 | 60.9 | 60.9 |
| a-2 M(Vi)—D₆₀—D(Ph²)₃₀—M(Vi) | 16.44 | 16.44 | 16.44 | 16.44 | 16.44 | 16.44 | 16.44 |
| a-3 D(Vi)₄ | 0.19 | 0.19 | 0.19 | 0.19 | 0.19 | 0.19 | 0.19 |
| a-4 M(Vi)₁₃—D(Ep)₂₄—T(Ph)₄₆—(OMe)₁₇ | 2.4 | 2.4 | 2.4 | 2.4 | 2.4 | 2.4 | 2.4 |
| b-1 M(H)—D(Ph²)—M(H) | 10.74 | 10.74 | 10.74 | 10.74 | 10.74 | 10.74 | 10.74 |
| b-2 M(H)₆₀—T(Ph)₄₀ | 4.72 | 4.72 | 4.72 | 4.72 | 4.72 | 4.72 | 4.72 |
| c-1 Fumed Silica | 4.3 | 4.3 | 4.3 | 4.3 | 4.3 | 4.3 | 4.3 |
| d-1 M—Dₙ—D((POE)R)ₘ—M | — | — | 0.05 | 0.1 | — | — | — |
| d-2 M—Dₙ—D((POE)(POP)R)ₘ—M | 0.1 | 0.3 | — | — | — | — | — |
| d-3 HO—(PO)ₘ—(EO)_{m′}—(Me₂SiO)ₙ—(EO)_{m′}—(PO)ₘ—OH | — | — | — | — | 0.1 | 0.3 | — |
| e-1 1-Ethyney1-1-Cyclohexanol | 0.3 | 0.3 | 0.3 | 0.3 | 0.3 | 0.3 | 0.3 |
| e-2 Bis Maleate | 0.01 | 0.01 | 0.01 | 0.01 | 0.01 | 0.01 | 0.01 |
| Total | 100.1 | 100.3 | 100.05 | 100.1 | 100.1 | 100.3 | 100 |
| f (Pt, ppm) | 4 | 4 | 4 | 4 | 4 | 4 | 4 |
| H/Vi ratio (mole) | 1.1 | 1.1 | 1.1 | 1.1 | 1.1 | 1.1 | 1.1 |
| Evaluation | | | | | | | |
| Viscosity (Pa · s @ 25° C., 10/s) | 23 | 24 | 23 | 24 | 23 | 24 | 22 |
| Thixotropic index | 3.47 | 3.50 | 3.47 | 3.54 | 3.44 | 3.47 | 3.37 |
| Refractive index | 1.48 | 1.48 | 1.48 | 1.48 | 1.48 | 1.48 | 1.48 |
| Aspect ratio after cure | 0.72 | 0.73 | 0.72 | 0.78 | 0.69 | 0.70 | 0.57 |
| Die share strength (N/cm²) | 1.12 | 1.12 | 1.15 | 1.15 | 1.10 | 1.10 | 1.03 |

TABLE 2

| | | Comp. |
|---|---|---|
| Components | Ex. 7 | Ex. 2 |
| a-3 D(Vi)₄ | 0.2 | 0.2 |
| a-4 M(Vi)₁₃-D(Ep)₂₄-T(Ph)₄₆-(OMe)₁₇ | 2.5 | 2.5 |
| a-5 M₅-M(Vi)₁₇-T₃₉-T(Ph)₃₉ | 62.39 | 62.39 |
| a-6 M(Vi)₃-T(Ph) | 3.3 | 3.3 |
| a-7 M(Vi)-D(Ph)₂₀-M(Vi) | 4.2 | 4.2 |
| b-1 M(H)-D(Ph₂)-M(H) | 19.4 | 19.4 |
| c-2 Silica-Titania Composite | 8 | 8 |
| d-1 M-Dₙ-D((POE)R)ₘ-M | 0.1 | — |
| e-1 1-Ethyney1-1-Cyclohexanol | 0.01 | 0.01 |
| Total | 100.1 | 100 |
| f (Pt, ppm) | 1.5 | 1.5 |
| H/Vi ratio (mole) | 0.8 | 0.8 |
| Evaluation | | |
| Viscosity (Pa · s @ 25° C., 10/s) | 20 | 20 |
| Thixotropic index | 3.5 | 3.5 |
| Refractive index | 1.51 | 1.51 |
| Aspect ratio after cure | 0.170 | 0.147 |

TABLE 3

| | | Comp. |
|---|---|---|
| Components | Ex. 8 | Ex. 3 |
| a-8 M(Vi)-D₅₃₀-M(Vi) | 39.6 | 39.6 |
| a-9 M₃₄-M(Vi)₁₁-Q₅₅ | 26.4 | 26.4 |
| a-10 M(Vi)-D₁₅₀-M(Vi) | 29.2 | 29.2 |
| b-3 MD(H)₅₀M | 4.2 | 4.2 |
| c-1 Fumed Silica | 5 | 5 |
| d-2 M-Dₙ-D((POE)(POP)R)ₘ-M | 0.3 | — |
| d-8 T(Ep)ₐ-D(Vi)_{b}-D_{c}-(OR)_{d} | 0.5 | — |
| e-1 1-Ethyneyl-1-Cyclohexanol | 0.1 | 0.1 |
| Total (a + b + e) | 100 | 100 |
| f (Pt, ppm) | 4 | 4 |
| H/Vi ratio (mole) | 1.3 | 1.3 |
| Evaluation | | |
| Viscosity (Pa · s @ 25° C., 10/s) | 14 | 15 |
| Thixotropic index | 5.8 | 5.8 |
| Aspect ratio after cure | 0.53 | 0.45 |

TABLE 4

| | | | Comp. |
|---|---|---|---|
| Components | Ex. 9 | Ex. 10 | Ex. 4 |
| a-1 M₁₄-M(Vi)₁₁-T₅₃-T(Ph)₂₂ | 60.9 | 60.9 | 60.9 |
| a-2 M(Vi)-D₆₀-D(Ph₂)₃₀-M(Vi) | 16.44 | 16.44 | 16.44 |
| a-3 D(Vi)₄ | 0.19 | 0.19 | 0.19 |
| a-4 M(Vi)₁₃-D(Ep)₂₄-T(Ph)₄₆-(OMe)₁₇ | 2.4 | 2.4 | 2.4 |
| b-1 M(H)-D(Ph₂)-M(H) | 10.74 | 10.74 | 10.74 |
| b-2 M(H)₆₀-T(Ph)₄₀ | 4.72 | 4.72 | 4.72 |
| c-1 Fumed Silica | 4.3 | 4.3 | 4.3 |
| d-2 M-Dₙ-D((POE)(POP)R)ₘ-M | 0.1 | 0.1 | — |
| d-4 Phenyl Trimethoxysilane | — | 0.3 | — |
| e-1 1-Ethyneyl-1-Cyclohexanol | 0.3 | 0.3 | 0.3 |
| e-2 Bis Maleate | 0.01 | 0.01 | 0.01 |
| Total | 100.1 | 100.4 | 100 |
| f (Pt, ppm) | 4 | 4 | 4 |
| H/Vi ratio (mole) | 1.1 | 1.1 | 1.1 |
| Evaluation | | | |
| Viscosity (Pa · s @ 25° C., 10/s) | 23 | 23 | 22 |
| Thixotropic index | 3.47 | 3.5 | 3.37 |
| Refractive index | 1.48 | 1.48 | 1.48 |
| Aspect ratio change (%) before/after cure | 2 | 9 | 14 |

TABLE 5

| | | | | | | Comp. | Comp. | Comp. | Comp. |
|---|---|---|---|---|---|---|---|---|---|
| | Ex. 11 | Ex. 12 | Ex. 13 | Ex. 14 | Ex. 15 | Ex. 5 | Ex. 6 | Ex. 7 | Ex. 8 |
| Components | | | | | | | | | |
| a-1 M₁₄—M(Vi)₁₁—T₅₃—T(Ph)₂₂ | 60.9 | 60.9 | 60.9 | 60.9 | 60.9 | 60.9 | 60.9 | 60.9 | 60.9 |
| a-2 M(Vi)—D₆₀—D(Ph₂)₃₀—M(Vi) | 16.44 | 16.44 | 16.44 | 16.44 | 16.44 | 16.44 | 16.44 | 16.44 | 16.44 |
| a-3 D(Vi)₄ | 0.19 | 0.19 | 0.19 | 0.19 | 0.19 | 0.19 | 0.19 | 0.19 | 0.19 |
| a-4 M(Vi)₁₃—D(Ep)₃₄—T(Ph)₄₅—(OMe)₁₇ | 2.4 | 2.4 | 2.4 | 2.4 | 2.4 | 2.4 | 2.4 | 2.4 | 2.4 |
| b-1 M(H)—D(Ph₂)—M(H) | 10.74 | 10.74 | 10.74 | 10.74 | 10.74 | 10.74 | 10.74 | 10.74 | 10.74 |
| b-2 M(H)₆₀—T(Ph)₄₀ | 4.72 | 4.72 | 4.72 | 4.72 | 4.72 | 4.72 | 4.72 | 4.72 | 4.72 |
| c-1 Fumed Silica | 4.3 | 4.3 | 4.3 | 4.3 | 4.3 | 4.3 | 4.3 | 4.3 | 4.3 |
| d-4 Phenyl Trimethoxysilane | 0.3 | — | — | — | — | — | — | — | — |
| d-5 Methyl Trimethoxysilane | — | 0.3 | — | — | — | — | — | — | — |
| d-6 3-Glycidoxypropyl Trimethoxysilane | — | — | 0.3 | — | — | — | — | — | — |
| d-7 3-Glycidoxypropyl Triethoxysilane | — | — | — | 0.3 | — | — | — | — | — |
| d-8 T(Ep)ₐ—D(Vi)_{b}—D_{c}—(OR)_{d} | — | — | — | — | 0.3 | — | — | — | — |
| d′-1 Methacryl Trimethoxysilane | — | — | — | — | — | — | 0.3 | — | — |
| d′-2 Octyl Trimethoxysilane | — | — | — | — | — | — | — | 0.3 | — |
| d′-3 Vinyl Trimethoxysilane | — | — | — | — | — | — | — | — | 0.3 |
| e-1 1-Ethyneyl-1-Cyclohexanol | 0.3 | 0.3 | 0.3 | 0.3 | 0.3 | 0.3 | 0.3 | 0.3 | 0.3 |
| e-2 Bis Maleate | 0.01 | 0.01 | 0.01 | 0.01 | 0.01 | 0.01 | 0.01 | 0.01 | 0.01 |
| Total | 100.3 | 100.3 | 100.3 | 100.3 | 100.3 | 100 | 100 | 100 | 100 |
| f (Pt, ppm) | 4 | 4 | 4 | 4 | 4 | 4 | 4 | 4 | 4 |
| H/Vi ratio (mole) | 1.1 | 1.1 | 1.1 | 1.1 | 1.1 | 1.1 | 1.1 | 1.1 | 1.1 |
| Evaluation | | | | | | | | | |
| Viscosity (Pa · s @ 25° C. 10/s) | 22 | 22 | 22 | 22 | 22 | 22 | 22 | 22 | 22 |
| Thixotropic index | 3.4 | 3.4 | 3.4 | 3.4 | 3.4 | 3.37 | 3.4 | 3.4 | 3.4 |
| Refractive index | 1.48 | 1.48 | 1.48 | 1.48 | 1.48 | 1.48 | 1.48 | 1.48 | 1.48 |
| Aspect ratio before/after cure | 0.6 | 0.6 | 0.6 | 0.6 | 0.6 | 0.6 | 0.6 | 0.6 | 0.6 |
| Viscosity change (%) before/after storage | 0 | 2 | 2 | 3 | 0 | >10 | >10 | >10 | >10 |

TABLE 6

| | Comp. | | | |
|---|---|---|---|---|
| Components | Ex. 9 | Ex. 16 | Ex. 17 | Ex. 18 |
| a-2 M(Vi)-D₆₀-D(Ph₂)₃₀-M(Vi) | 34 | 34 | 34 | 34 |
| a-3 D(Vi)₄ | 0.19 | 0.19 | 0.19 | 0.19 |
| a-4 M(Vi)₁₃-D(Ep)₂₄-T(Ph)₄₆-(OMe)₁₇ | 2.5 | 2.5 | 2.5 | 2.5 |
| a-11 M(Vi)₂₅-T(Ph)₇₅ | 43.1 | 43.1 | 43.1 | 43.1 |
| b-1 M(H)-D(Ph₂)-M(H) | 12.47 | 12.47 | 12.47 | 12.47 |
| b-2 M(H)₆₀-T(Ph)₄₀ | 4.7 | 4.7 | 4.7 | 4.7 |
| c-1 Fumed Silica | 3 | 3 | 3 | 3 |
| d-9 Glycidyloxypropyl (Dimethoxy)methylsilane | — | 0.75 | — | — |
| d-10 M(Vi)₂₅-T(Ph)₇₅-OH | — | — | 2.5 | — |
| d-11 Acrylic Acid (12% in aq.) | — | — | — | 0.75 |
| e-1 1-Ethyney1-1-Cyclohexanol | 0.03 | 0.03 | 0.03 | 0.03 |
| e-2 Bis Maleate | 0.01 | 0.01 | 0.01 | 0.01 |
| Total | 100 | 100.75 | 102.5 | 100.75 |
| f (Pt, ppm) | 4 | 4 | 4 | 4 |
| H/Vi ratio (mole) | 1.1 | 1.1 | 1.1 | 1.1 |
| Evaluation | | | | |
| Viscosity (Pa · s @ 25° C., 10/s) | 16 | 14 | 15 | 15 |
| Thixotropic index | 2.7 | 2.5 | 2.7 | 2.6 |
| Transmittance (%) | 50 | 65 | 60 | 66 |
| Aspect ratio change (%) before/after cure | 13 | 7 | 4 | 8 |

TABLE 7

| | Comp. | | Comp. | | |
|---|---|---|---|---|---|
| Components | Ex. 10 | Ex. 19 | Ex. 11 | Ex. 20 | Ex. 21 |
| a-12 M₄₅-M(Vi)₁₅-Q₄₀ | 5 | 5 | — | — | — |
| a-1 M₁₄-M(Vi)₁₁-T₅₃-T(Ph)₂₂ | 58.18 | 58.18 | 60.9 | 60.9 | 60.9 |
| a-3 D(Vi)₄ | 3.5 | 3.5 | 0.19 | 0.19 | 0.19 |
| a-4 M(Vi)₁₃-D(Ep)₂₄-T(Ph)₄₆-(OMe)₁₇ | 2.5 | — | 2.4 | — | — |
| a-7 M(Vi)-D(Ph)₂₀-M(Vi) | 4.75 | 4.75 | — | — | — |
| a-2 M(Vi)-D₆₀-D(Ph²)₃₀-M(Vi) | — | — | 16.44 | 16.44 | 16.44 |
| b-1 M(H)-D(Ph₂)-M(H) | 18.27 | 18.27 | 10.72 | 10.72 | 10.72 |
| b-4 M_{0.2}-M(H)₆₀-Q_{39.8} | 3 | 3 | — | — | — |
| b-2 M(H)₆₀-T(Ph)₄₀ | | | 4.72 | 4.72 | 4.72 |
| c-1 Fumed Silica | 4.5 | 4.5 | 4.3 | 4.3 | 4.3 |
| d-12 Condensation reaction product of | — | 2.5 | — | — | — |
| Glycidyloxypropyl (Trimethoxy)silanes | | | | | |
| d-13 HO(PhMeSiO)ₙH (n = 2 to 8) | — | — | — | 2.4 | — |
| d-4 Phenyl trimethoxy silane | — | — | — | — | 2.4 |
| e-1 1-Ethyney1-1-Cyclohexanol | 0.3 | 0.3 | 0.3 | 0.3 | 0.3 |
| e-2 Bismaleate | — | — | 0.01 | 0.01 | 0.01 |
| Total | 100 | 100 | 100 | 100 | 100 |
| f (Pt, ppm) | 4 | 4 | 4 | 4 | 4 |
| H/Vi ratio (mole) | 1.1 | 1.1 | 1.1 | 1.1 | 1.1 |
| Evaluation | | | | | |
| Viscosity (Pa · s @ 25° C., 10/s) | 8 | 14 | 22 | 23 | 20 |
| Thixotropic index | 5.4 | 5.9 | 3.4 | 4.0 | 5.8 |
| Refractive index | 1.47 | 1.47 | 1.48 | 1.48 | 1.48 |
| Aspect ratio after cure | 0.5 | 1.0 | 0.57 | 0.70 | 0.80 |

As can be seen from the results from Tables 1 to 3, the embodiments of the curable silicone composition according to the present invention including the (C1) side chain polyether-modified organopolysiloxane showed a high aspect ratio of the dome-shaped composition after curing. This result indicates that the composition according to the present invention is morphologically stable even at a high temperature, such as from 150° C. to 190° C.

Also, as can be seen from the results from Table 1, the embodiments of the curable silicone composition according to the present invention including the (C1) side chain polyether-modified organopolysiloxane showed a high die share strength. This result indicates that the composition according to the present invention possess an improved adhesion property.

Also as can be seen from Table 4, the embodiments of Example 9, which comprises the (C1) side chain polyether-modified organopolysiloxane, and of Example 10, which comprises both of the (C1) side chain polyether-modified organopolysiloxane and the (C2) organosilane compound, showed the smaller aspect ratio change (%) before/after cure of the dispensed dome shape than that of the comparative example. This result indicates that the composition according to the present invention is more morphologically stable.

Also, as can be seen from Table 5, the compositions according to Examples 11 to 15, which comprise the (C) additive of the present invention, showed no or smaller change in the viscosity after storage compared to the comparative examples. These results indicate that the composition according to the present invention possesses a long shelf life.

Furthermore, as can be seen from Table 6, the compositions according to Examples 16 to 18, which comprise the (C) additive of the present invention, showed the smaller aspect ratio change (%) before/after cure of the dispensed dome shape than that of the comparative example. This result indicates that the composition according to the present invention is more morphologically stable. In addition, these examples showed higher transmittance property than the comparative example, indicating that the composition according to the present invention can provide cure products having a high transparency.

Also, as can be seen from the results from Table 7, the embodiment of the curable silicone composition according to the present invention including the (C) additive of the present invention showed a high aspect ratio of the dome-shaped composition after curing. This result indicates that the composition according to the present invention is morphologically stable even at a high temperature, such as from 150° C. to 190° C.

It can be therefore said that the curable silicone compositions according to the present invention are very useful for encapsulation applications in the manufacture of semiconductor packages, in particular LED packages.

1. A curable silicone composition comprising:
(A) at least one curing reactive organopolysiloxane in an amount of 65% by weight or more relative to the total weight of the composition;
(B) at least one inorganic filler selected from silica, silica-titania composite oxide particle, and a combination thereof, in an amount of 1% by weight or more relative to the total weight of the composition; and
(C) at least one additive selected from (C1) organopolysiloxane having at least one organic functional group including at least one polyether structure at molecular side chain and/or molecular terminal; (C2) organosilane compound comprising at least one organic functional group selected from a C₁-C₆ alkyl group, aryl group, and epoxy group; (C3) organopolysiloxane having at least one hydroxy group and at least one aryl group; (C4) organosiloxane oligomer having at least one epoxy group; (C5) unsaturated carboxylic acid or an ester thereof, and combinations thereof.

2. The composition according to claim 1, wherein the (A) curing reactive organopolysiloxane is hydrosilylation reaction-reactive organopolysiloxane.

3. The composition according to claim 1, wherein the (B) inorganic filler is present in an amount of more than 1.5% by weight and 30% by weight or less relative to the total weight of the composition.

4. The composition according to claim 1, wherein the (C3) organopolysiloxane having at least one hydroxy group comprises the hydroxy group(s) in an amount of 0.1 mol % or more relative to the total amount of the silicon atom-bonded functional groups.

5. The composition according to claim 1, comprising (C1) organopolysiloxane having at least one organic functional group including at least one polyether structure at molecular side chain and/or molecular terminal.

6. The composition according to claim 5, wherein the (C1) organopolysiloxane is present in an amount of 0.01% by weight or more and 10% by weight or less relative to the total weight of the composition.

7. The composition according to claim 1, comprising (C2) organosilane compound comprising at least one organic functional group comprising at least one C₁-C₆ alkyl group, aryl group, and/or epoxy group.

8. The composition according to claim 7, wherein the (C2) organosilane compound is present in an amount of 0.01% by weight or more and 5% by weight or less relative to the total weight of the composition.

9. The composition according claim 1, comprising both of the (C1) organopolysiloxane having at least one organic functional group including at least one polyether structure at molecular side chain and/or molecular terminal and (C2) organosilane compound comprising at least one organic functional group comprising at least one C₁-C₆ alkyl group, aryl group, and/or epoxy group.

10. A sealing material formed with the curable silicone composition according to claim 1.

11. An optical semiconductor device provided with the sealing material according to claim 10.
